(19) United States
(12) Patent Application Publication
(10) Pub. No.: US 2026/0150537 A1
(43) Pub. Date: May 28, 2026

(54) DISPLAY PANEL AND ELECTRONIC APPARATUS INCLUDING THE SAME

(71) Applicant: SAMSUNG DISPLAY CO., LTD., YONGIN-SI (KR)

(72) Inventors: Daehyun Kim, YONGIN-SI (KR); Donghwi Kim, YONGIN-SI (KR); Changkyu Jin, YONGIN-SI (KR); Hyeonjun Yoon, YONGIN-SI (KR); Jaeho Choi, YONGIN-SI (KR)

(21) Appl. No.: 19/383,951

(22) Filed: Nov. 10, 2025

(30) Foreign Application Priority Data
Nov. 26, 2024 (KR) 10-2024-0171477
Mar. 11, 2025 (KR) 10-2025-0031664

(51) Int. Cl. H10K 59/131; H10K 59/121

(52) U.S. Cl. CPC H10K 59/131; H10K 59/1213

(57) ABSTRACT

A display panel includes a first data line and a second data line arranged along a first direction, each of the first data line and the second data line extending in a second direction crossing the first direction. A first switching transistor transmits a first data signal from the first data line to a first switching node located in a direction further away from the second data line with respect to the first data line in response to a scan signal. A first common line is located between the first switching node and the first data line in the first direction and extending in the second direction. A first constant voltage is applied to the first common line.

### CROSS-REFERENCE TO RELATED APPLICATION

This application claims priority under 35 U.S.C. § 119 to Korean Patent Application No. 10-2024-0171477, filed on Nov. 26, 2024 in the Korean Intellectual Property Office (KIPO), and Korean Patent Application No. 10-2025-0031664, filed on Mar. 11, 2025 in KIPO, the disclosures of which are incorporated by reference in their entireties herein.

### 1. Technical Field

One or more embodiments relate to a display panel and an electronic apparatus including the same, and more particularly, to a display panel capable of displaying high-quality images and an electronic apparatus including the display panel.

### 2. Discussion of Related Art

Display panels are applied to an increasing variety of electronic apparatuses along with the advancement of the information society. In the display panels, the pixel sizes may decrease to display high quality images with an increased resolution. Therefore, a variety of electronic components may need to be placed in a relatively small area.

In the case of a display panel and an electronic apparatus including the same, according to the related art, high-quality images cannot be displayed due to electrical interference between electronic components adjacent to each other since a distance between the electronic components decreases as a size of pixels decreases.

### SUMMARY

One or more embodiments include a display panel capable of displaying high-quality

images and an electronic apparatus including the same. However, the embodiments are examples and do not limit the scope of the disclosure.

Additional aspects will be set forth in part in the description which follows and, in part, will be apparent from the description, or may be learned by practice of the presented embodiments of the disclosure.

According to an embodiment of the present disclosure, a display panel includes a first data line and a second data line arranged along a first direction, each of the first data line and the second data line extending in a second direction crossing the first direction. A first switching transistor transmits a first data signal from the first data line to a first switching node located in a direction further away from the second data line with respect to the first data line in response to a scan signal. A first common line is located between the first switching node and the first data line in the first direction and extending in the second direction. A first constant voltage is applied to the first common line.

In an embodiment, the display panel may further include a second switching transistor transmitting a second data signal from the second data line to a second switching node located in a direction further away from the first data line with respect to the second data line in response to the scan signal, and a second common line which is located between the second switching node and the second data line in the first direction, which extends in the second direction, and to which a second constant voltage is applied.

In an embodiment, a level of the first constant voltage may be different from a level of the second constant voltage.

In an embodiment, the display panel may further include a third data line located in the direction further away from the first data line with respect to the second data line and extending in the second direction, and a connection electrode electrically connected to the second common line. The second switching node is located between the second common line and the third data line in the first direction, and the connection electrode is located between the second switching node and the third data line in the first direction.

In an embodiment, the second switching node and the connection electrode may extend in the second direction.

In an embodiment, a length of the connection electrode in the second direction may be greater than a length of the second switching node in the second direction.

In an embodiment, the second common line and the connection electrode may be integrally formed as a single unitary indivisible body.

In an embodiment, the second common line may have a potential of a reference voltage to be transmitted to the first switching node and the second switching node.

In an embodiment, the display panel may further include a third data line located in a direction further away from the first data line with respect to the first switching node and extending in the second direction, a third switching transistor transmitting a third data signal from the third data line to a third switching node located between the third data line and the first switching node in the first direction, in response to the scan signal, and a connection electrode located between the third data line and the third switching node in the first direction. The connection electrode is disposed over the first data line and is electrically connected to a power line transmitting a driving voltage.

In an embodiment, the connection electrode and the third switching node may extend in the second direction.

In an embodiment, a length of the connection electrode in the second direction may be greater than a length of the third switching node in the second direction.

According to an embodiment of the present disclosure, an electronic apparatus includes a processor and a display panel controlled by the processor. The display panel includes a first data line and a second data line arranged along a first direction, each of the first data line and the second data line extending in a second direction crossing the first direction. A first switching transistor transmitting a first data signal from the first data line to a first switching node located in a direction further away from the second data line with respect to the first data line in response to a scan signal. A first common line is located between the first switching node and the first data line in the first direction and extending in the second direction, and to which a first constant voltage is applied.

In an embodiment, the electronic apparatus may further include a second switching transistor transmitting a second data signal from the second data line to a second switching node located in a direction further away from the first data line with respect to the second data line in response to the scan signal, and a second common line which is located between the second switching node and the second data line in the first direction and extending in the second direction, and to which a second constant voltage is applied.

In an embodiment, the electronic apparatus may further include a third data line located in the direction further away from the first data line with respect to the second data line and extending in the second direction, and a connection electrode electrically connected to the second common line, wherein the second switching node is located between the second common line and the third data line in the first direction, and the connection electrode is located between the second switching node and the third data line in the first direction.

In an embodiment, the second switching node and the connection electrode may extend in the second direction.

In an embodiment, a length of the connection electrode in the second direction may be greater than a length of the second switching node in the second direction.

In an embodiment, the second common line and the connection electrode may be integrally formed as a single unitary indivisible body.

In an embodiment, the electronic apparatus may further include a third data line located in a direction further away from the first data line with respect to the first switching node and extending in the second direction, a third switching transistor transmitting a third data signal from the third data line to a third switching node located between the third data line and the first switching node in the first direction, in response to the scan signal, and a connection electrode located between the third data line and the third switching node in the first direction. The connection electrode is disposed over the first data line and is electrically connected to a power line transmitting a driving voltage.

In an embodiment, the connection electrode and the third switching node may extend in the second direction.

In an embodiment, a length of the connection electrode in the second direction may be greater than a length of the third switching node in the second direction.

Other aspects, features, and advantages other than those described above will become apparent from the following detailed description, the appended claims, and the accompanying drawings.

### BRIEF DESCRIPTION OF THE DRAWINGS

The above and other aspects, features, and advantages of certain embodiments

of the disclosure will be more apparent from the following description taken in conjunction with the accompanying drawings, in which:

FIG. 1 is a block diagram schematically illustrating an electronic apparatus according to an embodiment;

FIG. 2 illustrates schematic diagrams of electronic apparatuses according to embodiments;

FIG. 3 is a schematic diagram illustrating a case where electronic apparatuses are wearable electronic apparatuses, according to embodiments;

FIG. 4 is a schematic diagram illustrating a case where an electronic apparatus is a vehicle electronic apparatus, according to embodiments;

FIG. 5 is a schematic plan view of a display module including a display panel according to an embodiment;

FIG. 6 is a schematic side view of the display module of FIG. 5 according to an embodiment;

FIG. 7 is a schematic plan view of the display module of FIG. 5 according to an embodiment;

FIG. 8 is an equivalent circuit diagram showing a pixel circuit electrically connected to a display element included in the display module of FIG. 7 according to an embodiment;

FIG. 9 is a waveform diagram showing an electrical signal applicable to the pixel circuit of FIG. 8 according to an embodiment;

FIG. 10 is a layout diagram schematically illustrating locations of transistors, a capacitor, etc. in pixels of the display module of FIG. 7 according to an embodiment;

FIGS. 11 to 16 are layout diagrams schematically illustrating, layer by layer, components, such as the transistors, the capacitor, etc. illustrated in FIG. 10 according to embodiments;

FIG. 17 is a cross-sectional view schematically illustrating a cross-section of the display module taken along line A-A′ of FIG. 10 according to an embodiment;

FIG. 18 is an equivalent circuit diagram showing a pixel circuit electrically connected to a display element included in a display module according to an embodiment;

FIG. 19 is an equivalent circuit diagram showing a pixel circuit electrically connected to a display element included in a display module according to an embodiment; and

FIG. 20 is a plan view schematically illustrating one conductive layer included in a display module according to an embodiment.

### DETAILED DESCRIPTION OF EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, non-limiting embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As various modifications may be applied and numerous embodiments may be implemented, particular embodiments will be illustrated in the drawings and described in detail in the written description. Effects and features, and methods for achieving them will be clarified with reference to embodiments described below in detail with reference to the drawings. However, embodiments of the present disclosure may have different forms and should not be construed as being limited to the descriptions set forth herein.

Hereinafter, non-limiting embodiments will now be described in detail with reference to the accompanying drawings. When described with reference to the drawings, identical or corresponding elements will be given the same reference numerals, and redundant description of these elements will be omitted.

In the following embodiments, it will be understood that when an element, such as a layer, film, region, or plate, is referred to as being “on” another element, the element may be “directly on” the other element or indirectly on the other element with intervening elements therebetween. Also, sizes of elements in the drawings may be exaggerated or reduced for convenience of descriptions. For example, since sizes and thicknesses of elements in the drawings may be arbitrarily illustrated for convenience of descriptions, the described embodiments are not necessarily limited thereto.

In the following embodiments, the x-axis, the y-axis, and the z-axis are not necessarily limited to three axes of the rectangular coordinate system, and may be interpreted in a broader sense. For example, the x-axis, y-axis, and z-axis may be orthogonal to each other, but may refer to different directions that are not orthogonal to each other and cross each other at various different angles.

In the following embodiments, while terms such as “first” and “second” are used to describe various elements, these elements are not limited by these terms. These terms are only used to distinguish one element from another element.

It will be understood that terms “comprise,” “include,” and “have” used herein specify the presence of stated features or elements, but do not preclude the presence or addition of one or more other features or elements.

As used herein, the expression such as “A and/or B” indicates A, B, or A and B. Also, the expression such as “at least one of A and B” indicates A, B, or A and B.

In the following embodiments, it will be understood that when a layer, region, or element is referred to as being “connected to” or “coupled to” another layer, region, or element, it may be directly or indirectly connected or coupled to the other layer, region, or element. For example, intervening layers, regions, or elements may be present. For example, as used herein, when a layer, region, or element is referred to as being electrically connected to another element, it may be directly electrically connected to the other layer, region, or element or indirectly electrically connected to the other layer, region, or element via intervening layers, regions, or elements.

The present disclosure concerns a display panel includes first to third pixels arranged along a first direction. A first common line having a constant voltage applied thereto that is disposed between a first switching node of the second pixel and a first data line to prevent or minimize electrical influence on the first switching node from the first data line during the emission period of the second pixel. A second common line has a constant voltage applied thereto is disposed between a second switching node of the third pixel and a second data line to prevent or minimize electrical influence on the second switching node from the second data line during the emission period of the third pixel. A connection electrode of the first pixel may be disposed between a third switching node of the first pixel and a third data line. The connection electrode may receive a constant voltage, such as a driving voltage. The connection electrode of the first pixel prevents or minimizes the third switching node from being affected by the third data line. Accordingly, the display panel may display high quality images.

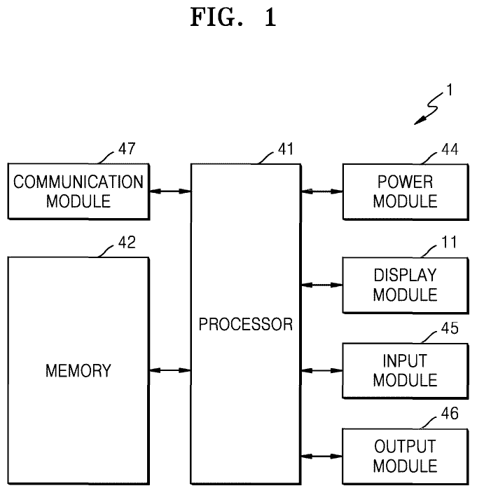

FIG. 1 is a schematic block diagram of an electronic apparatus 1 according to an embodiment. According to the present embodiment, the electronic apparatus 1 may include a display apparatus and modules having additional functions in addition to a display module 11.

As shown in FIG. 1, according to the present embodiment, the electronic apparatus 1 may include the display module 11, a processor 41, a memory 42, a power module 44, an input module 45, an output module 46, and a communication module 47.

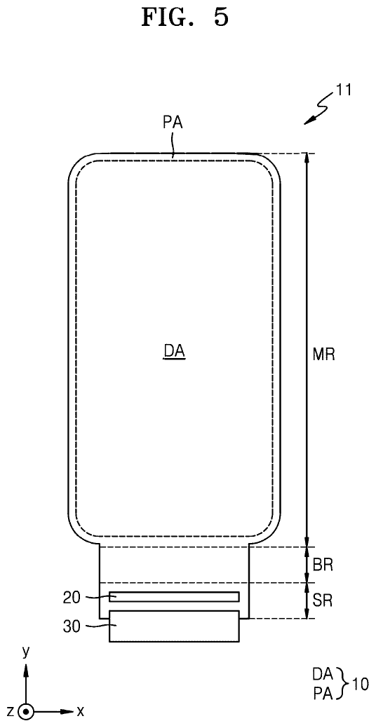

The display module 11 may include a display panel 10 (see FIG. 5) as described below. For example, the display module 11 may include the display panel 10 and a data driver 20 mounted thereon. The display panel 10 is described below.

The processor 41 may control most of the components of the electronic apparatus 1. For example, the processor 41 may output digital video data to the display module 11 such that the display module 11 may display an image and may receive input data from the input module 45 such that a function according to the input data may be performed in the electronic apparatus 1. The processor 41 may include at least one of a central processing unit (CPU), an application processor (AP), a graphics processing unit (GPU), a communication processor (CP), and an image signal processor (ISP).

In some embodiments, the processor 41 may be divided into two or more processors from a functional or structural point of view. For example, the processor 41 may include a main processor in the form of a first driving chip including a CPU, and an auxiliary processor in the form of a second driving chip which is a portion of the display module 11. The auxiliary processor in the form of the second driving chip may include a controller configured to receive an image signal from the main processor and process the image signal according to interface specifications of the display panel 10 including the display module 11.

The memory 42 may include at least one of a nonvolatile memory and a volatile memory. The memory 42 may store data information required for the operation of the processor 41 or the display module 11. When the processor 41 executes an application stored in the memory 42, an input control signal and/or a data signal for an image may be transmitted to the display module 11, and the display module 11 may output image information by processing the received signal.

The power module 44 may include a power supply module, such as a power adapter or a battery apparatus, and a power conversion module configured to generate power required for the operation of the electronic apparatus 1 by converting power supplied by the power supply module. Power conversion performed by the power conversion module may include direct current (DC)-DC conversion, alternating current (AC)-DC conversion, and DC-AC conversion. However, one or more embodiments are not necessarily limited thereto.

The input module 45 may provide input information to the processor 41 and/or the display module 11. The input module 45 may include a physical button, a keyboard, and a microphone, as well as various sensor modules. Examples of the sensor modules may include a touch sensor, a pressure sensor, a distance sensor, a position sensor, a digitizer, a motion recognition sensor, a camera sensor, a light reception sensor, a photoelectric conversion sensor, and/or a temperature sensor. Also, the sensor modules may include biosensors, such as a blood pressure sensor, a blood glucose sensor, an electrocardiogram sensor, and/or a heart rate sensor.

The output module 46 may receive information other than the image received from the processor 41 and provide the information to a user. The output module 46 may include, for example, an acoustic module, a haptic module, and/or a light-emitting module. Also, the output module 46 may include a unique functional module of the electronic apparatus 1, such as a cooling module of a refrigerator.

For reference, the display module 11 may also perform an output function. For example, the display panel 10 included in the display module 11 may display (e.g., output) information processed by the electronic apparatus 1. For example, the display panel 10 may be configured to display execution screen information of an application driven in the electronic apparatus 1, or to display user interface (UI) or graphic user interface (GUI) information according to the execution screen information. The display panel 10 may include a display layer configured to display an image, and a touch screen layer configured to detect a touch input from the user. Accordingly, the display panel 10 may function as a portion of the input module 45 configured to provide an input interface between the electronic apparatus 1 and the user and may also function as a portion of the output module 56 configured to provide an output interface between the electronic apparatus 1 and the user.

The communication module 47 is a module configured to transmit and receive information between the electronic apparatus 1 and an external apparatus and may include a receiver and a transmitter. The communication module 47 may include various wireless communication modules, such as a mobile communication module, a broadcast reception module, a wireless Internet module, a short-range communication module, a wireless-fidelity (Wi-Fi) module, and/or a Bluetooth module, or various wired communication modules.

The electronic apparatus 1 shown in FIG. 1 is only an example, and for example, a display apparatus without a communication function may not include the communication module 47. Also, for example, when the electronic apparatus 1 includes a display apparatus, at least one of the components of the electronic apparatus 1 described above may be included in the display apparatus. In addition, some of individual modules functionally included in a single module may be included in the display apparatus, and others thereof may be included in the electronic apparatus 1 separate from the display apparatus. For example, the display apparatus may include the display module 11, while the processor 41, the memory 42, and the power module 44 may be components of the electronic apparatus 1 other than the display apparatus. Alternatively, various modifications are possible. The display apparatus may include the display module 11 and the power module 44, and the power module 44 may supply power to the components of the electronic apparatus 1, such as the processor 41 and the memory 42.

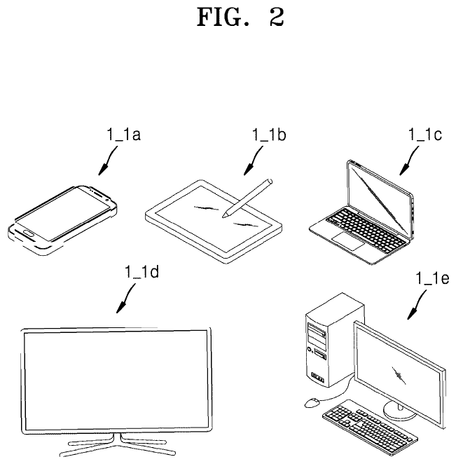

FIG. 2 illustrates schematic diagrams of electronic apparatuses 1 according to embodiments. In FIG. 2, a smartphone 1_1a, a table personal computer (PC) 1_1b, a laptop computer 1_1c, a television (TV) 1_1d, and a desktop monitor 1_1e are shown as examples of the electronic apparatus 1. However, embodiments of the present disclosure are not necessarily limited thereto and the electronic apparatuses 1 may include various different small-sized, medium-sized and large-sized electronic devices.

The smartphone 1_1a may include the processor 41, the memory 42, the power module 44, and the display module 11, as well as the input module 45, such as a touch sensor, and the communication module 57. The smartphone 1_1a may process information received via the communication module 47 or another input module and display the information via the display module 11.

Similar to the smartphone 1_1a, each of the tablet PC 1_1b, the laptop computer 1_1c, the TV 1_1d, and/or the desktop monitor 1_1e may include the display module 11 and the input module 45, and in some cases, may also include the communication module 47.

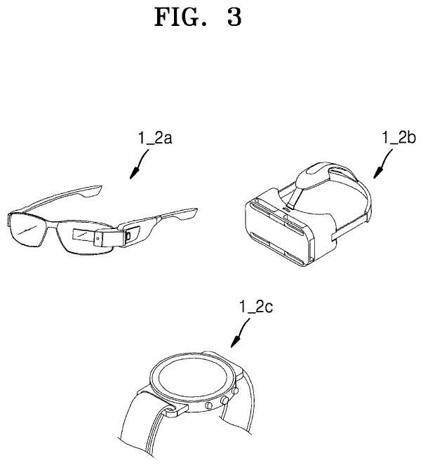

FIG. 3 is a schematic diagram illustrating a case where the electronic apparatuses 1 are wearable electronic apparatuses, according to embodiments. In FIG. 3, smart glasses 1_2a, a head mount display 1_2b, and a smart watch 1_2c are shown as examples of the electronic apparatus 1.

The smart glasses 1_2a and the head mount display 1_2b may each include the display module 11 configured to display an image, and a reflector configured to reflect a display surface that displays the image and provide the same to a user's eyes. The user may experience virtual reality or augmented reality by using the electronic apparatus 1.

The smart watch 1_2c may include a biometric sensor as the input module 45 and may provide biometric information identified by the biometric sensor to the user via the display module 11.

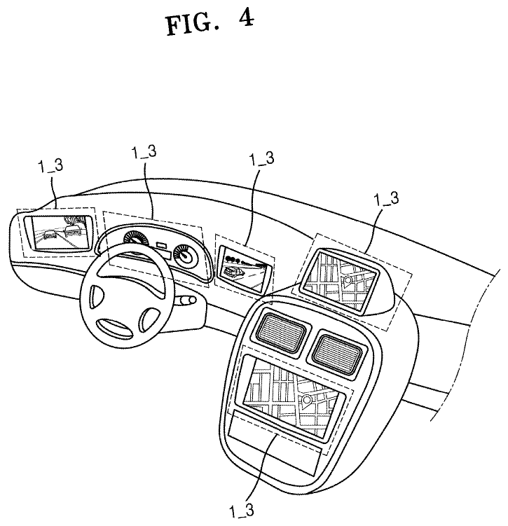

FIG. 4 is a schematic diagram illustrating a case where the electronic apparatus 1 is a vehicle electronic apparatus 1_3, according to embodiments. As shown in FIG. 4, the vehicle electronic apparatus 1_3 may include a display of a cluster of a vehicle, a display of an instrument panel of a vehicle, a center information display (CID) of a center fascia or a dashboard of a vehicle, or a room mirror display replacing a side mirror of a vehicle.

However, the electronic apparatus 1 according to one or more embodiments is not necessarily limited to the above description. For example, according to an embodiment, the electronic apparatus 1 may include not only apparatuses mainly used as displays, such as billboards, electronic boards, and/or game consoles, but also various home appliances configured to display information via the display module 11, such as refrigerators, washing machines, drying machines, air conditioners, and/or robot vacuum cleaners. Also, when the display module 11 has a function of transmitting light, the electronic apparatus 1 may include a smart window or a transparent display apparatus configured to display a background and a display image together. However, the electronic apparatus 1 according to one or more embodiments is not necessarily limited thereto, and the electronic apparatus 1 including the display panel 10 to be described below may fall within the scope of the one or more embodiments.

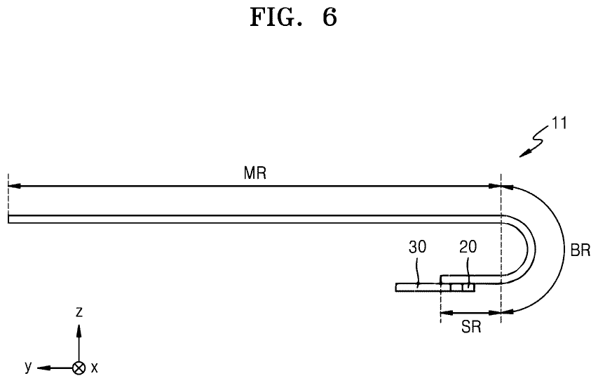

FIG. 5 is a schematic plan view of the display module 11 including the display panel 10, according to an embodiment, and FIG. 6 is a schematic side view of the display module 11 of FIG. 5. The display module 11 included in the electronic apparatus 1 described above may include the display panel 10 as shown in FIGS. 5 and 6. This applies to the following embodiments and modifications thereof.

In a plan view, the display panel 10 may appear to have an approximately rectangular shape. For example, in an embodiment as shown in FIG. 5, the display panel 10 may have an approximately rectangular shape having short sides in a first direction (e.g., an x-axis direction) and long sides in a second direction (e.g., a y-axis direction) on a xy-plane. In this case, an edge where a short side in the first direction (x-axis direction) and a long side in the second direction (y-axis direction) meet may form a right angle, or may have a round shape with a certain curvature. However, in the plan view, the display panel 10 may have a polygonal shape other than the rectangular shape, or may have an elliptical shape, an irregular shape, etc.

The display panel 10 may include a display area DA and a peripheral area PA outside the display area DA (e.g., in a plan view). The display area DA may be an area where an image is displayed, and a plurality of pixels may be located in the display area DA. The display area DA may have other various shapes, such as a circular shape, an elliptical shape, a polygonal shape, a specific figure shape, etc. FIG. 5 illustrates that the display area DA has an approximately rectangular shape with round edges.

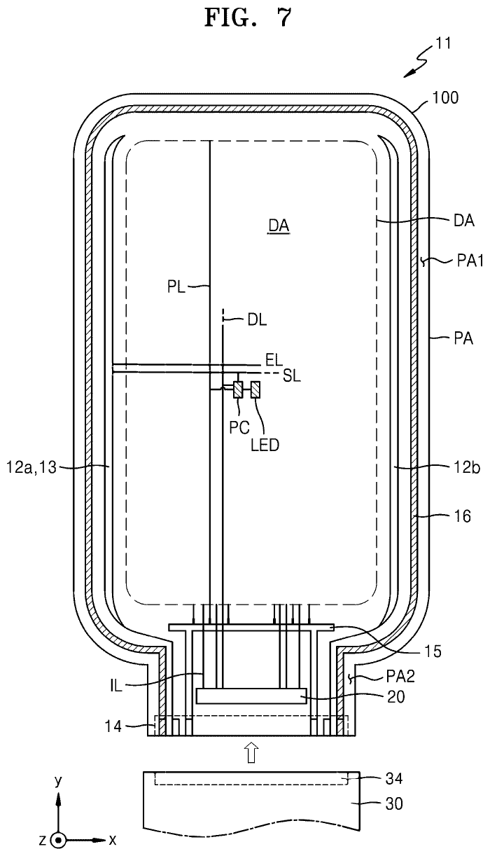

In an embodiment, a shape of the plane of the display panel 10 shown in FIG. 5 may be substantially identical to a shape of a substrate 100 (see FIG. 7) included in the display panel 10. When the display panel 10 includes the display area DA and the peripheral area PA outside the display area DA (e.g., in a plan view), it may be understood that the substrate 100 may include the display area DA and the peripheral area PA outside the display area DA (e.g., in a plan view). Hereinbelow, for convenience of description, it is described that the substrate 100 includes the display area DA and the peripheral area PA.

The display panel 10 may include a main region MR, a bending region BR outside the main region MR, and a subregion SR spaced apart from the main region MR with the bending region BR therebetween. The main region MR may be located on one side of the bending region BR (e.g., the y-axis direction), and the subregion SR may be located on the other side of the bending region BR. As shown in FIG. 6, the display panel 10 may be bent in the bending region BR, and when viewed in a third direction (e.g., the z-axis direction), at least a portion of the subregion SR may overlap the main region MR.

FIG. 6 illustrates that the display panel 10 is in a bent state, but one or more embodiments are not necessarily limited thereto. For example, the display panel 10 may include a foldable display panel, and in this case, the display panel 10 may be bent in the display area DA with respect to a bending axis crossing the display area DA. However, when necessary, the display panel 10 may not be bent. The subregion SR may include a non-display area.

As described above, the display panel 10 may include a rigid display panel that is relatively strong and thus is not easily bent, or a flexible display panel that has flexibility and thus is bendable, foldable, or rollable. For example, the display panel 10 may include a foldable display panel that may be folded or unfolded, a curved display panel having a curved display surface, a bent display panel in which areas other than a display surface are bent, a rollable display panel that may be rolled or unrolled, or a stretchable display panel that may be stretched.

The display module 11 including the display panel 10 may include the data driver 20 mounted in the subregion SR of the display panel 10. The data driver 20 may be disposed on the display panel 10 in the form of an integrated circuit (IC). For example, the data driver 20 may be a data driving IC configured to generate data signals. As described above, the data driver 20 may include an auxiliary processor in the form of a second driving chip, and may be a portion of the processor 41.

A display circuit board 30 may be attached to (e.g., attached directly thereto) an end of the subregion SR of the display panel 10. For example, in some embodiments the display module 11 may include the display circuit board 30. The display circuit board 30 may be electrically connected to the data driver 20 via a pad of the subregion SR of the display panel 10.

FIG. 7 is a schematic plan view of the display module 11 of FIG. 5. As shown in FIG. 7, the display panel 10 included in the display module 11 may include the substrate 100. Various components included in the display panel 10 may be disposed over the substrate 100.

In an embodiment, the substrate 100 may include glass, ceramic, a metal, or polymer resin. In an embodiment, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. In an embodiment, the substrate 100 may have a multilayer structure including two layers each including the polymer resin and an inorganic layer therebetween. Alternatively, the substrate 100 may have a structure in which a layer including the polymer resin and an inorganic layer are alternately stacked. The inorganic material layer may include silicon oxide, silicon nitride, or silicon oxynitride.

The pixels may be disposed in the display area DA, and the display area DA may display images using light emitted from the pixels. Each pixel may include a display element, such as a light-emitting diode LED, and the display element may be electrically connected to a pixel circuit PC. The pixel circuit PC and the light-emitting diode LED may be disposed in the display area DA. In FIG. 7, for convenience, the pixel circuit PC and the light-emitting diode LED are shown as being positioned side by side; however, the pixel circuit PC and the light-emitting diode LED may overlap at least partially. As an example, the light-emitting diode LED may be disposed on the pixel circuit PC.

A gate driving circuit, a pad 14, a power supply line 15, and a common voltage supply line 16 may be disposed in the peripheral area PA. The gate driving circuit may include, for example, a first scan driving circuit 12a, a second scan driving circuit 12b, and/or an emission control driving circuit 13.

The first scan driving circuit 12a may provide a scan signal to the pixel circuit PC through a gate line SL. The second scan driving circuit 12b may be arranged on the opposite side from the first scan driving circuit 12a with the display area DA therebetween (e.g., in the x-axis direction). Some of the pixel circuits PC disposed in the display area DA may be electrically connected to the first scan driving circuit 12a, and the remaining ones may be connected to the second scan driving circuit 12b. However, embodiments of the present disclosure are not necessarily limited thereto. For example, in an embodiment, the second scan driving circuit 12b may be omitted.

In an embodiment, the emission control driving circuit 13 may be disposed on the first scan driving circuit 12a side. The emission control driving circuit 13 may provide an emission control signal to the pixel P through an emission control line EL. In FIG. 7, the emission control driving circuit 13 is disposed on only one side of the display area DA. However, one or more embodiments are not necessarily limited thereto. For example, the display panel 10 may include the emission control driving circuits 13 disposed on one side and the other side of the display area DA. Alternatively, the display panel 10 may comprise the first scan driving circuit 12a arranged on one side of the display area DA, and the emission control driving circuit 13 arranged on the other side of the display area DA.

In an embodiment, the peripheral area PA may include a first peripheral area PA1 surrounding at least a portion of the display area DA, and a second peripheral area PA2 located at a side of the display area DA (e.g., a lower side in the-y-axis direction) and extending in a first direction (e.g., the x-axis direction). In an embodiment, a width of the second peripheral area PA2 in the first direction (e.g., the x-axis direction) may be less than a width of the display area DA. Through this structure, at least a portion of the second peripheral area PA2 may be easily bent.

The pad 14 may be disposed in the second peripheral area PA2 of the substrate 100. The pad 14 may be exposed by not being covered by an insulating layer, and may be electrically connected to the display circuit board 30. A pad 34 of the display circuit board 30 may be electrically connected to the pad 14 of the display panel 10.

The display circuit board 30 is configured to transmit signals of a controller or power to the display panel 10. In an embodiment, the display circuit board 30 may be, for example, a printed circuit board or a flexible printed circuit board. Control signals generated by the controller may be transmitted to the gate driving circuit through the display circuit board 30. In addition, the controller may provide a driving voltage ELVDD and a common voltage ELVSS to the power supply line 15 and the common voltage supply line 16, respectively. The driving voltage ELVDD may be provided to each pixel circuit PC through a driving voltage line PL connected to the power supply line 15, and the common voltage ELVSS may be provided to a common electrode of the light-emitting diode LED connected to the common voltage supply line 16. The power supply line 15 may extend in the first direction (e.g., the x-axis direction). In an embodiment, the common voltage supply line 16 may have a loop shape (e.g., in a plan view) having one open side and partially surround the display area DA.

A data signal of the data driver 20 may be transmitted to the pixel circuit PC through an input line IL and a data line DL electrically connected to the input line IL.

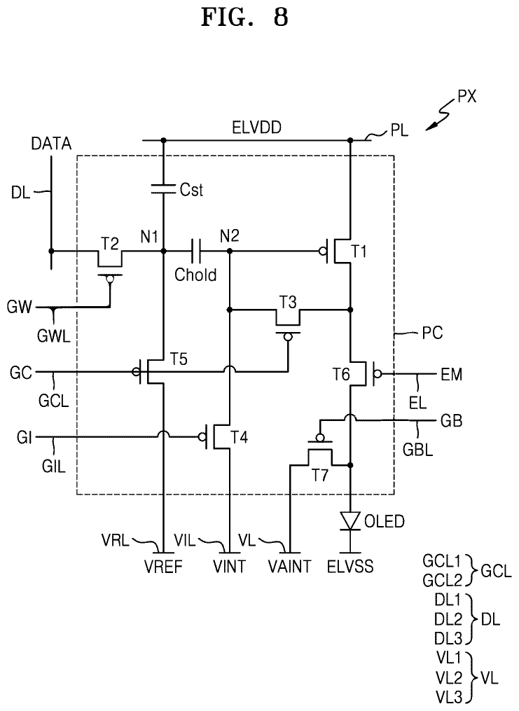

FIG. 8 is an equivalent circuit diagram showing the pixel circuit PC which may be electrically connected to the display element, such as the light emitting diode LED, included in the display panel 10 of the display module 11 of FIG. 7.

The display panel 10 may have a plurality of pixels PX in the display area DA. Each of pixels PX may include the display element, such as the light-emitting diode LED, and the pixel circuit PC which may be electrically connected to the display element. FIG. 8 shows that the pixel PX includes an organic light-emitting diode OLED as the display element. The pixel circuit PC shown in FIG. 8 may be a pixel circuit PC included in any one pixel PX located in the N^{th} row of the display area DA.

In an embodiment, the pixel circuit PC may include a plurality of transistors T1, T2, T3, T4, T5, T6, and T7 and a plurality of capacitors Cst and Chold as shown in FIG. 8. In one or more embodiments, the number of transistors and the number of capacitors included in the pixel circuit PC are not necessarily limited to those shown in FIG. 8 and may be changed. For example, the pixel circuit PC may include seven transistors and one capacitor, or it may include nine transistors and two capacitors. Hereinafter, for convenience of descriptions, it is described that the pixel circuit PC includes seven transistors T1, T2, T3, T4, T5, T6, and T7 and two capacitors Cst and Chold as shown in FIG. 8.

The pixel circuit PC may be electrically connected to a first scan line GWL configured to transmit a first scan signal GW, a second scan line GCL configured to transmit a second scan signal GC, a third scan line GIL configured to transmit a third scan signal GI, a fourth scan line GBL configured to transmit a fourth scan signal GB, an emission control line EL configured to transmit the emission control signal EM, and the data line DL configured to transmit the data signal DATA. In addition, the pixel circuit PC may be electrically connected to a power line PL configured to transmit a driving voltage ELVDD, a first initialization voltage line VIL configured to transmit a first initialization voltage VINT, a second initialization voltage line VL configured to transmit a second initialization voltage VAINT, and a reference voltage line VRL configured to transmit a reference voltage VREF. A common voltage ELVSS may be applied to a common electrode of the organic light-emitting device OLED electrically connected to the pixel circuit PC.

In an embodiment, the data line DL may include a first data line DL1 electrically connected to pixels located in the second column, a second data line DL2 electrically connected to pixels located in the third column, and a third data line DL3 electrically connected to pixels located in the first column.

In an embodiment, a first transistor T1, which is a driving transistor, may include a gate electrode electrically connected to a first electrode of a holding capacitor Chold, a first region (e.g., a source region) electrically connected to the power line PL, and a second region (e.g., a drain region), and thus the first transistor T1 may control an amount of current flowing to the organic light-emitting diode OLED in response to an electrical signal applied to the gate electrode.

A gate electrode of the first transistor T1 may be electrically connected to a second region (e.g., a drain region) of a third transistor T3 and a second region (e.g., a drain region) of a fourth transistor T4. The first region of the first transistor T1 may be electrically connected to the power line PL. In one embodiment, another transistor may be interposed between the first region of the first transistor T1 and the power line PL. The second region of the first transistor T1 is electrically connected to a first region (e.g., a source region) of the third transistor T3 and a first region (e.g., a source region) of a sixth transistor T6. The current from the first transistor T1 may be transmitted to the organic light-emitting diode OLED via the sixth transistor T6 such that the organic light-emitting diode OLED emits light. In this way, the brightness of light emitted by the organic light-emitting diode OLED may be determined by the amount of current from the first transistor T1.

For reference, when a region of one transistor and a region of another transistor are electrically connected, the region of one transistor and the region of another transistor may electrically connected to each other by a connection electrode, or the region of one transistor and the region of another transistor may be integrally formed as a single unitary indivisible body. For example, a semiconductor layer of one transistor and a semiconductor layer of another transistor may be integrally formed as a single unitary indivisible body. This applies to the following embodiments and modifications thereof.

A second transistor T2, which is a switching transistor, may include a gate electrode electrically connected to the first scan line GWL transmitting the first scan signal GW, a first region (e.g., a source region) electrically connected to the data line DL transmitting the data signal DATA, and a second region (e.g., a drain region) electrically connected to a second electrode of the holding capacitor Chold. In an embodiment, the second transistor T2 may be turned on by the first scan signal GW such that the data signal DATA may be stored in the holding capacitor Chold. The second region of the second transistor T2 may be electrically connected to not only the second electrode of the holding capacitor Chold but also a second region (e.g., a drain region) of a fifth transistor T5 and a first electrode of a storage capacitor Cst. Each of the second region of the second transistor T2, the second region of the fifth transistor T5, the first electrode of the storage capacitor Cst, and the second electrode of the holding capacitor Chold may have a same electric potential and may be regarded as a first node N1.

The holding capacitor Chold may include the first electrode and the second electrode. The first electrode of the holding capacitor Chold may be electrically connected to the gate electrode of the first transistor T1 to form a second node N2. The first electrode of the holding capacitor Chold and the gate electrode of the first transistor T1 may be integrally formed as a single unitary indivisible body as described below. The second electrode of the holding capacitor Chold may be electrically connected to the second region of the second transistor T2, the second region of the fifth transistor T5, and the first electrode of the storage capacitor Cst. The second electrode of the holding capacitor Chold and the first electrode of the storage capacitor Cst may be integrally formed as a single unitary indivisible body as described below. The holding capacitor Chold may receive the data signal DATA from the second transistor T2 such that the gate electrode of the first transistor T1 has electric potential of the data signal DATA.

The storage capacitor Cst may include the first electrode electrically connected to the second electrode of the holding capacitor Chold and a second electrode electrically connected to the power line PL. The first electrode of the storage capacitor Cst may be electrically connected to the second region of the second transistor T2 and the second region of the fifth transistor T5 as described above. The first electrode of the storage capacitor Cst and the second electrode of the holding capacitor Chold may be integrally formed as a single unitary indivisible body. For example, one electrode may be the first electrode of the storage capacitor Cst and at the same time the second electrode of the holding capacitor Chold. In an embodiment, the storage capacitor Cst may prevent or minimize the electric potential of the second electrode of the holding capacitor Chold which is the first node N1 from being affected by electric signal from a neighboring component.

The third transistor T3, which is a compensation transistor, may include a gate electrode electrically connected to the second scan line GCL transmitting the second scan signal GC, the first region electrically connected to the second region of the first transistor T1, and the second region electrically connected to the first electrode of the holding capacitor Chold. In an embodiment, the third transistor T3 may be turned in response to the second scan signal GC and electrically connect the gate electrode of the first transistor T1 and the second region of the first transistor T1 to diode-connect the first transistor T1. Through this, the third transistor T3 may form a compensation path which may compensate for the threshold voltage of the first transistor T1, thereby allowing the threshold voltage of the first transistor T1 to be transmitted to the first electrode of the holding capacitor Chold. As a result, even if the threshold voltages of the first transistors T1 included in the pixels PX are different from one another, the first transistors T1 of the pixels PX to which the same data signal DATA is applied may output the same or similar amount of current flowing to the organic light-emitting diodes OLED.

The fourth transistor T4, which may be a first initialization transistor, may include the gate electrode electrically connected to the third scan line GIL transmitting the third scan signal GI, a first region (e.g., a source region) electrically connected to the first initialization voltage line VIL transmitting the first initialization voltage VINT, and the second region (e.g., the drain region) electrically connected to the gate electrode of the first transistor T1. The second region of the fourth transistor T4 may be electrically connected to not only the gate electrode of the first transistor T1 but also the first electrode of the holding capacitor Chold and the second region of the third transistor T3. In an embodiment, the fourth transistor T4 may be turned on in response to the third scan signal GI to initialize the first electrode of the holding capacitor Chold and the gate electrode of the first transistor T1, such as the second node N2, to the first initialization voltage VINT.

The fifth transistor T5, which may be a reference voltage transistor, may include the gate electrode electrically connected to the second scan line GCL transmitting the second scan signal GC, a first region (e.g., a source region) electrically connected to the reference voltage line VRL transmitting the reference voltage VREF, and the second region (e.g., the drain region) electrically connected to the second electrode of the holding capacitor Chold. The second region of the fifth transistor T5 may be electrically connected to not only the second electrode of the holding capacitor Chold, but also the first electrode of the storage capacitor Cst and the second region of the second transistor T2. In an embodiment, the fifth transistor T5 may be turned on by the second scan signal GC to initialize the second electrode of the holding capacitor Chold and the first electrode of the storage capacitor Cst, such as the first node N1, to the reference voltage VREF.

FIG. 8 shows that the second scan line GCL transmits the second scan signal GC to the third transistor T3 which is the compensation transistor and the fifth transistor T5 which is the reference voltage transistor, but one or more embodiments are not necessarily limited thereto. For example, in an embodiment the second scan line GCL may include a second-1 scan line GCL1 transmitting the second scan signal GC to the fifth transistor T5 and a second-2 scan line GCL2 transmitting the second scan signal GC to the third transistor T3.

The sixth transistor T6, which may be an emission control transistor, may include a gate electrode electrically connected to the emission control line EL transmitting the emission control signal EM, the first region (e.g., the source region) electrically connected to the second region of the first transistor T1, and a second region (e.g., a drain region) electrically connected to a pixel electrode of the organic light-emitting diode OLED. The first region of the sixth transistor T6 may be electrically connected to not only the second region of the first transistor T1 but also the first region of the third transistor T3, and the second region of the sixth transistor T6 may be electrically connected to not only the pixel electrode of the organic light-emitting diode OLED but also a second region (e.g., a drain region) of a seventh transistor T7. In an embodiment, the sixth transistor T6 may be turned on in response to the emission control signal EM such that the current from the first transistor T1 flows to the organic light-emitting diode OLED.

The seventh transistor T7, which may be a second initialization transistor, may include a gate electrode electrically connected to the fourth scan line GBL transmitting the fourth scan signal GB, a first region (e.g., a source region) electrically connected to the second initialization voltage line VL transmitting the second initialization voltage VAINT, and the second region (e.g., the drain region) electrically connected to the pixel electrode of the organic light-emitting diode OLED. The second region of the seventh transistor T7 may be electrically connected to not only the pixel electrode of the organic light-emitting diode OLED but also the second region of the sixth transistor T6. In an embodiment, the seventh transistor T7 may be turned on in response to the fourth scan signal GB and initialize the electric potential of the pixel electrode of the organic light-emitting diode OLED to the second initialization voltage VAINT.

The second initialization voltage VAINT required for the pixel electrode of the organic light-emitting diode OLED may differ for each pixel. For example, in an embodiment the second initialization voltage VAINT required for the pixel electrode of the organic light-emitting diode OLED of a pixel emitting red light, the second initialization voltage VAINT required for the pixel electrode of the organic light-emitting diode OLED of a pixel emitting green light, and the second initialization voltage VAINT required for the pixel electrode of the organic light-emitting diode OLED of a pixel emitting blue light may be different from one another. Accordingly, the second initialization voltage line VL may include a second-1 initialization voltage line VL1 for a first pixel emitting red light, a second-2 initialization voltage line VL2 for a second pixel emitting green light, and a second-3 initialization voltage line VL3 for a third pixel emitting blue light.

For reference, FIG. 8 shows that each of the transistors is a PMOS (P-channel MOSFETs), but one or more embodiments are not necessarily limited thereto. For example, at least one transistor may be an NMOS (N-channel MOSFET), or each of the transistors may be NMOS. In an embodiment in which at least one transistor is an NMOS, a first region of the transistor may be the drain region and a second region of the transistor may be the source region. For reference, a PMOS thin film transistor may be turned on when an electrical signal applied to a gate electrode of the PMOS thin film transistor is a low level signal (low voltage signal), and may be turned off when the electrical signal applied to the gate electrode of the PMOS thin film transistor is a high level signal (high voltage signal). The NMOS thin film transistor may be turned on when an electrical signal applied to a gate electrode of the NMOS thin film transistor is a high level signal (high voltage signal), and may be turned off when the electrical signal applied to the gate electrode of the NMOS thin film transistor is a low level signal (low voltage signal). Hereinafter, for convenience of descriptions, it is described that each of the transistors is PMOS (P-channel MOSFETs).

The organic light-emitting diode OLED may include the pixel electrode electrically connected to the second region of the sixth transistor T6, the common electrode integrally formed as a single unitary indivisible body throughout the plurality of pixels PX, and an intermediate layer interposed between the pixel electrode and the common electrode and including at least an emission layer. The common voltage ELVSS may be applied to the common electrode. The organic light-emitting diode OLED may emit light with a brightness corresponding to the current determined by the first transistor T1.

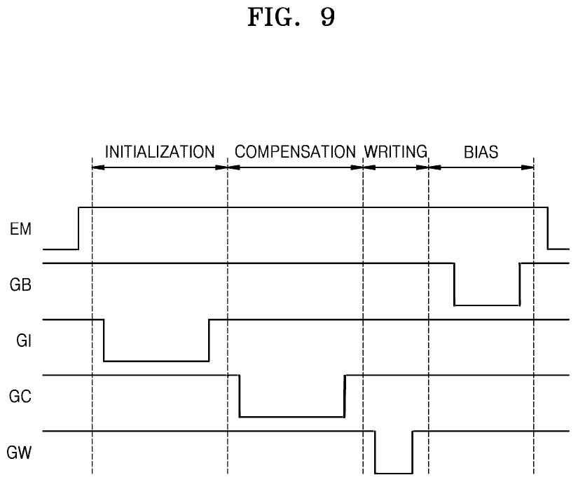

Below, with reference to FIG. 9, which is a waveform diagram showing an electrical signal which may be applied to the pixel circuit PC of FIG. 8, the operation of the pixel circuit PC of FIG. 8 is briefly described.

As shown in FIG. 9, when a signal applied to a pixel is divided into periods, the periods may be divided into an initialization period, a compensation period, a writing period, and a bias period. In an embodiment, a period in which the emission control signal EM has a low level signal may be referred to as an emission period.

When the emission control signal EM becomes a high level signal, the emission period may end. A period where the emission control signal EM is the high level signal may include the initialization period, the compensation period, the writing period, and the bias period.

The initialization period may be a period where the third scan signal GI is approximately a low level signal. In the initialization period, the fourth transistor T4 to which the third scan signal GI is applied is turned on so that a voltage (e.g., an electric potential) of the first electrode of the holding capacitor Chold, the gate electrode of the first transistor T1, and the second region of the third transistor T3, which are electrically connected to the second region of the fourth transistor T4, is initialized to the first initialization voltage VINT. The first initialization voltage VINT may be a low level signal which may turn on the first transistor T1. As a result, the first transistor T1 may be turned on in the initialization period.

When the initialization period ends, the compensation period may be entered. For example, when the third scan signal GI is changed to a high level signal, the initialization period ends, and the compensation is entered, in which the second scan signal GC is approximately a low level signal. In the compensation period, the third transistor T3 and the fifth transistor T5 which receive the second scan signal GC may be turned on.

When the fifth transistor T5 is turned on, the electric potential of the second electrode of the holding capacitor Chold, the first electrode of the storage capacitor Cst, and the second region of the second transistor T2, which are electrically connected to the second region of the fifth transistor T5, may be initialized to the reference voltage VREF. For example, the first node N1 may be initialized to the reference voltage VREF. The third transistor T3 is also turned on to electrically connect the second region of the first transistor T1 and the gate electrode of the first transistor T1 to each other. In the initialization period, the driving voltage ELVDD input to the first region of the first transistor T1 is output to the second region of the first transistor T1, and the second region of the first transistor T1 may be electrically connected to the gate electrode of the first transistor T1 by the third transistor T3 during the compensation period. As a result, the electric potential of the gate electrode of the first transistor T1, such as the electric potential of the second node N2, gradually increases from the first initialization voltage VINT, and when the electric potential of the second node N2 corresponds to a threshold voltage Vth (Vth is a (-) value) of the first transistor T1, the first transistor T1 is turned off. Therefore, the electric potential of the gate electrode of the first transistor T1 may become the threshold voltage Vth of the first transistor T1. After the compensation period, the second electrode of the holding capacitor Chold may have the reference voltage VREF, and the first electrode of the holding capacitor Chold may have the threshold voltage Vth of the first transistor T1.

When the compensation period ends, the writing period is entered. For example, when the second scan signal GC changes to a high level signal, the compensation period ends, and the writing period in which the first scan signal GW is approximately a low level signal begins. In the writing period, the second transistor T2 to which the first scan signal GW is applied is turned on.

When the second transistor T2 is turned on, the data signal DATA is transmitted to the first node N1 which is the second region of the second transistor T2, through the second transistor T2, so that the electric potential of the second region of the second transistor T2, the second electrode of the holding capacitor Chold, the first electrode of the storage capacitor Cst, and the second region of the fifth transistor T5, each of which is the first node N1, may be changed into the data signal DATA. The electric potential of the second electrode of the storage capacitor Cst, which is maintained as the reference voltage VREF in the compensation period, is changed to the data signal VDATA in the writing period. In this case, the electric potential of the first electrode of the holding capacitor Chold is changed in proportion to an amount of change of the electric potential of the second electrode of the holding capacitor Chold. Since the change of the electric potential of the second electrode of the holding capacitor Chold is the difference between the data signal DATA and the reference voltage VREF, the electric potential of the first electrode of the holding capacitor Chold changes by a value which is proportional to this difference from the threshold voltage Vth. Accordingly, the electric potential of the first electrode of the holding capacitor Chold is lowered, and a degree to which the first transistor T1 is turned on during the emission period is determined by the lowered voltage of the gate electrode of the driving transistor T1, so that the amount of the output current from the first transistor T1 may be determined.

When the writing period ends, the bias period is entered. For example, when the first scan signal GW changes to a high level signal, the write period ends and the bias period in which the fourth scan signal GB is approximately a low level signal is entered. In the bias period, the seventh transistor T7 to which the fourth scan signal GB is applied is turned on.

When the seventh transistor T7 is turned on, the electric potential of the pixel electrode of the organic light-emitting diode OLED and the second region of the sixth transistor T6 which are electrically connected to the second region of the seventh transistor T7 is initialized to the second initialization voltage VAINT. Since the electric potential of the pixel electrode of the organic light-emitting diode OLED is initialized in this way, the bias period may also be referred to as a pixel electrode initialization period.

When the bias period ends, the emission period is entered. For example, when the fourth scan signal GB changes to a high level signal, the bias period ends and the emission period in which the emission control signal EM is approximately a low level signal is entered. In the emission period, the sixth transistor T6 to which the emission control signal EM is applied is turned on.

When the sixth transistor T6 is turned on, the output current from the second region of the first transistor T1, which is determined according to the electric potential of the gate electrode of the first transistor T1, is transmitted to the organic light-emitting diode OLED through the turned-on sixth transistor T6, so that the organic light-emitting diode OLED may emit light. FIG. 9 shows only a portion of the emission period for convenience, however, the emission period is the longest among the various periods. When the emission period ends, the initialization period described above may be entered.

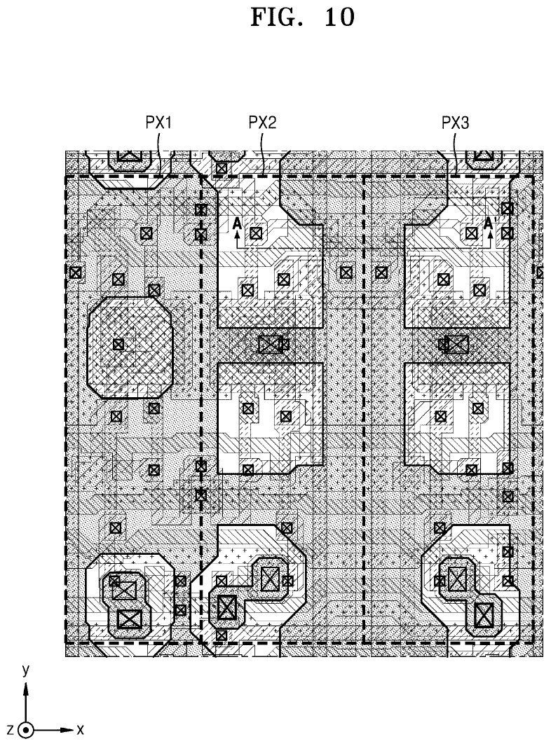

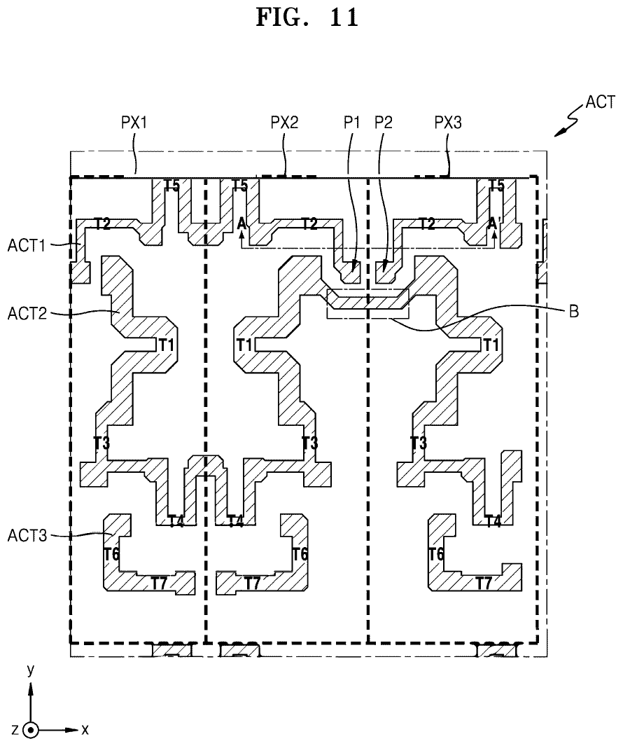

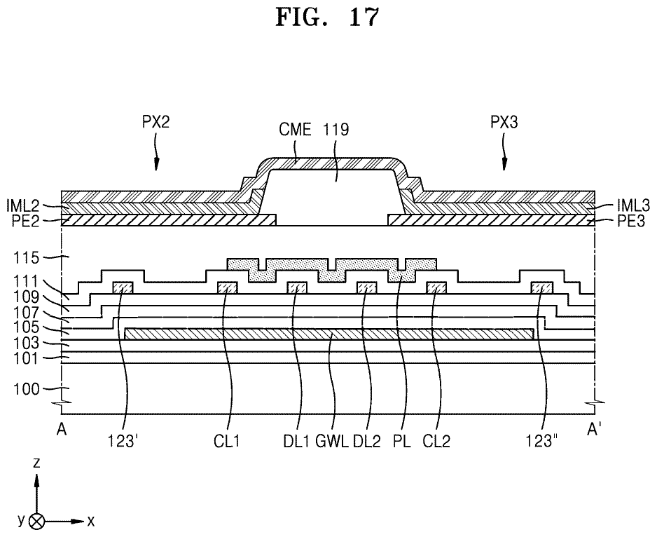

FIG. 10 is a layout diagram schematically showing the locations of the plurality of transistors T1, T2, T3, T4, T5, T6 and T7, the plurality of capacitors Cst and Chold, etc. in pixels PX included in the display panel 10 of the display module of FIG. 7, FIGS. 11 to 16 are layout diagrams schematically illustrating, layer by layer, components, such as the plurality of transistors T1, T2, T3, T4, T5, T6 and T7, the plurality of capacitors Cst and Chold, etc. shown in FIG. 10, and FIG. 17 is a cross-sectional view schematically illustrating a cross-section of the display panel 10 taken along line A-A′ of FIG. 17. Sizes of components in the cross-sectional view may be exaggerated or reduced for convenience of descriptions.

As shown in FIGS. 10 to 16, the display panel 10 and the electronic apparatus 1 having the display panel 10 may have a structure in which sets each of which includes a first pixel PX1, a second pixel PX2, and a third pixels PX3 sequentially arranged in the first direction (e.g., the x-axis direction) are repeatedly arranged in the first direction (x-axis direction). In an embodiment, these sets may also be repeatedly arranged in the second direction (e.g., the y-axis direction). In one or more embodiments, each of the pixels adjacent to the first pixel PX1 in the +y direction and the-y direction may be the second pixel PX2, each of the pixels adjacent to the second pixel PX2 in the +y direction and the-y direction may be the third pixel PX3, and each of the pixels adjacent to the third pixel PX3 in the +y direction and the-y direction may be the first pixel PX1.

For reference, regions where the first pixel PX1, the second pixel PX2, and the third pixel PX3 are located in FIGS. 10 to 16 may denote regions where the pixel circuit included in the first pixel PX1, the pixel circuit included in the second pixel PX2, and the pixel circuit included in the third pixel PX3 are located. A display element included in the first pixel PX1 does not necessarily have to be located within the region indicated by the first pixel PX1. For example, in one or more embodiments, a first pixel electrode electrically connected to the pixel circuit included in the first pixel PX1 may be located across the region indicated as the first pixel PX1 and the region indicated as the second pixel PX2. A second pixel electrode electrically connected to the pixel circuit included in the second pixel PX2 may be located in the-y direction from the first pixel electrode and may be located across the region indicated as the first pixel PX1 and the region indicated as the second pixel PX2. A third pixel electrode electrically connected to the pixel circuit included in the third pixel PX3 may be located across the region indicated as the second pixel PX2 and the region indicated as the third pixel PX3, and may also be located across the regions indicated as the second and third pixels PX2 and PX3 and the regions of pixels located in the-y direction from the second and third pixels PX2 and PX3. In this embodiment, the first pixel electrodes and the second pixel electrodes may be alternately located in one column, and the third pixel electrodes may be located in another column, and these two columns may be arranged alternately along the first direction (e.g., the x-axis direction).

The pixel circuit of the first pixel PX1 may be a first-color pixel circuit, the pixel circuit of the second pixel PX2 may be a second-color pixel circuit, and the pixel circuit of the third pixel PX3 may be a third-color pixel circuit. For example, in an embodiment the first-color may be red, the second-color may be green, and the third-color may be blue. However, embodiments of the present disclosure are not necessarily limited thereto.

In an embodiment, the first pixel PX1 and the second pixel PX2 neighboring each other (e.g., adjacent to each other in the x-axis direction) may be approximately mirror-symmetrical with respect to a boundary between the first pixel PX1 and the second pixel PX2. In the case of the second pixel PX2 and the third pixel PX3, they may be approximately mirror-symmetrical with respect to a boundary between the second pixel PX2 and the third pixel PX3 (e.g., in the x-axis direction).

Hereinbelow, for convenience of descriptions, some components are described based on the pixel circuit of the first pixel PX1, but these components may also be located symmetrically or identically in the second pixel PX2 and/or in the third pixel PX3.

A buffer layer 101 (see FIG. 17) including an inorganic insulating material such as silicon oxide, silicon nitride and/or silicon oxynitride may be disposed over the substrate 100 (e.g., directly thereon in the z-axis direction). The buffer layer 101 may prevent metal atoms or impurities from diffusing from the substrate 100 to a semiconductor layer ACT disposed thereon. In addition, the buffer layer 101 may allow the semiconductor layer ACT to be uniformly crystallized by adjusting a providing speed of heat during a crystallization process for forming the semiconductor layer ACT.

The semiconductor layer ACT shown in FIG. 11 may be disposed on the buffer layer 101. The semiconductor layer ACT may include a silicon semiconductor. As an example, in an embodiment the semiconductor layer ACT may include amorphous silicon or polycrystalline silicon. In the latter case, the semiconductor layer ACT may include polycrystalline silicon crystallized at low temperature. In one or more embodiments, ions may be implanted in at least a portion of the semiconductor layer ACT. In one or more embodiments, a lower metal layer approximately corresponding to the shape of the semiconductor layer ACT may be disposed under the semiconductor layer ACT to protect the semiconductor layer ACT. In this case, an insulating layer may be disposed between the lower metal layer and the semiconductor layer ACT.

In an embodiment, the semiconductor layer ACT in the first pixel PX1 may include a first semiconductor layer ACT1, a second semiconductor layer ACT2, and a third semiconductor layer ACT3 arranged in the y-axis direction and separated from one another. One or more embodiments are not necessarily limited thereto, and in some embodiments, at least two of the first semiconductor layer ACT1, the second semiconductor layer ACT2, and the third semiconductor layer ACT3 may be integrally formed as a single unitary indivisible body.

In an embodiment, the first semiconductor layer ACT1 of the first pixel PX1 and the first semiconductor layer ACT1 of the second pixel PX2 adjacent to the first pixel PX1 in the +x direction may be integrally formed as a single unitary indivisible body. In contrast, the first semiconductor layer ACT1 of the second pixel PX2 and the first semiconductor layer ACT1 of the third pixel PX3 adjacent to the second pixel PX2 in the +x direction may be spaced apart from each other. In an embodiment, the second semiconductor layer ACT2 of the first pixel PX1, the second semiconductor layer ACT2 of the second pixel PX2, and the second semiconductor layer ACT2 of the third pixel PX3 may be integrally formed as a single unitary indivisible body. In an embodiment, each of the third semiconductor layer ACT3 of the first pixel PX1, the third semiconductor layer ACT3 of the second pixel PX2, and the third semiconductor layer ACT3 of the third pixel PX3 may be spaced apart from each other.

Each of the first semiconductor layer ACT1, the second semiconductor layer ACT2, and the third semiconductor layer ACT3 may have a shape curved in various shapes (e.g., in a plan view). The first transistor T1, the second transistor T2, the third transistor T3, the fourth transistor T4, the fifth transistor T5, the sixth transistor T6, and the seventh transistor T7 may be located along the first semiconductor layer ACT1, the second semiconductor layer ACT2, and the third semiconductor layer ACT3.

In one embodiment, the second transistor T2 which is the switching transistor and the fifth transistor T5 which is the reference voltage transistor may be located along the first semiconductor layer ACT1, the first transistor T1 which is the driving transistor, the third transistor T3 which is the compensation transistor, and the fourth transistor T4 which is the first initialization transistor may be located along the second semiconductor layer ACT2, and the sixth transistor T6 which is the emission control transistor and the seventh transistor T7 which is the second initialization transistor may be located along the third semiconductor layer ACT3. The first semiconductor layer ACT1 may include a channel region of each of the second transistor T2 and the fifth transistor T5, a source region on one side of the channel region, and a drain region on the other side of the channel region. Similarly, the second semiconductor layer ACT2 may include a channel region of each of the first transistor T1, the third transistor T3, and the fourth transistor T4, a source region on one side of the channel region, and a drain region on the other side of the channel region. The third semiconductor layer ACT3 may also include a channel region of each of the sixth transistor T6 and the seventh transistor T7, a source region on one side of the channel region, and a drain region on the other side of the channel region. In FIG. 11, the positions of the channel regions of the transistors T1, T2, T3, T4, T5, T6, and T7 are denoted by reference symbols of the transistors T1, T2, T3, T4, T5, T6, and T7. A source region and a drain region are located on one side and the other side of a channel region.

A first gate insulating layer 103 (see FIG. 7) may cover the semiconductor layer ACT and be disposed on the substrate 100 (or the buffer layer 101). The first gate insulating layer 103 may include an insulating material. As an example, in an embodiment the first gate insulating layer 103 may include silicon oxide, silicon nitride, silicon oxynitride, or aluminum oxide.

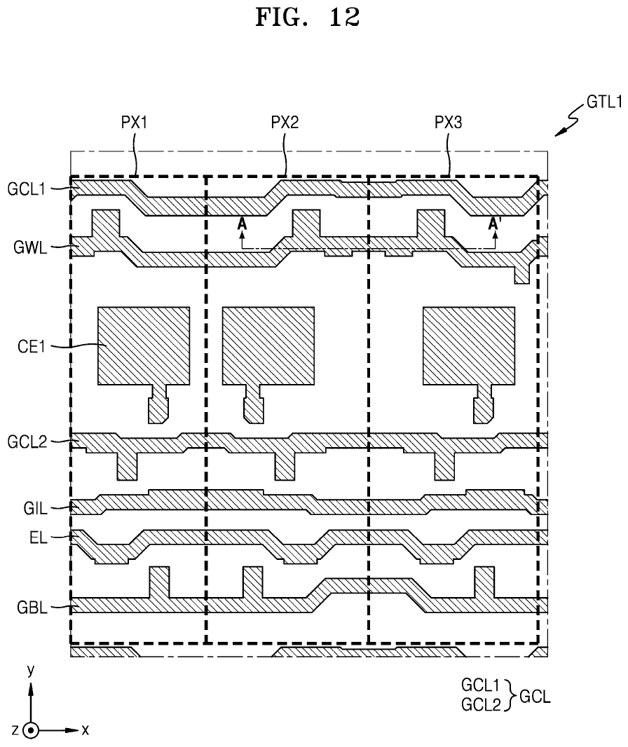

A first gate layer GTL1 shown in FIG. 12 may be disposed on the first gate insulating layer 103 (e.g., disposed directly thereon in the z-axis direction). In an embodiment, the first gate layer GTL1 may include the first scan line GWL transmitting the first scan signal GW to the second transistor T2 which is the switching transistor, the second scan line GCL transmitting the second scan signal GC to the third transistor T3 which is the compensation transistor and the fifth transistor T5 which is the reference voltage transistor and including the second-1 scan line GCL1 and the second-2 scan line GCL2, the third scan line GIL transmitting the third scan signal GI to the fourth transistor T4 which is the first initialization transistor, the fourth scan line GBL transmitting the fourth scan signal GB to the seventh transistor T7 which is the second initialization transistor, the emission control line EL transmitting the emission control signal EM to the sixth transistor T6 which is the emission control transistor, and a first capacitor electrode CE1 which is the first electrode of the holding capacitor Chold and has an isolated shape. The first capacitor electrode CE1 may also function as a driving gate electrode of the first transistor T1 which is the driving transistor.

Each of the first scan line GWL, the second-1 scan line GCL1, the second-2 scan line GCL2, the third scan line GIL, the fourth scan line GBL, and the emission control line EL may extend approximately in the first direction (e.g., the x-axis direction) and may be integrally formed as a single unitary indivisible body throughout a plurality of pixels. Portions of the first scan line GWL, the second-1 scan line GCL1, the second-2 scan line GCL2, the third scan line GIL, the fourth scan line GBL, and the emission control line EL which overlap the semiconductor layer ACT may function as gate electrodes of the transistors.

For example, a portion of the first scan line GWL overlapping the first semiconductor layer ACT1 (e.g., in the z-axis direction) may be the gate electrode of the second transistor T2 which is the switching transistor, a portion of the second-1 scan line GCL1 overlapping the first semiconductor layer ACT1 (e.g., in the z-axis direction) may be the gate electrode of the fifth transistor T5 which is the reference voltage transistor, a portion of the second-2 scan line GCL2 overlapping the second semiconductor layer ACT2 (e.g., in the z-axis direction) may be the gate electrode of the third transistor T3 which is the compensation transistor, the portion of the third scan line GIL overlapping the second semiconductor layer ACT2 may be the gate electrode of the fourth transistor T4 which is the first initialization transistor, a portion of the fourth scan line GBL overlapping the third semiconductor layer ACT3 (e.g., in the z-axis direction) may be the gate electrode of the seventh transistor T7 which is the second initialization transistor, and a portion of the emission control line EL overlapping the third semiconductor layer ACT3 may be the gate electrode of the sixth transistor T6 which is the emission control transistor.

In one or more embodiments, the first semiconductor layer ACT1 may have a bent shape and the first scan line GWL may have a protrusion, so that the first scan line GWL may overlap the first semiconductor layer ACT1 twice. In this embodiment, the second transistor T2 which is the switching transistor may be a dual gate transistor having two gate electrodes and two channel regions. In an embodiment, the second-1 scan line GCL1 may overlap the portion of the first semiconductor layer ACT1 where the first semiconductor layer ACT1 is bent twice, so that the second-1 scan line GCL1 may overlap the first semiconductor layer ACT1 twice. Therefore, the fifth transistor T5 which is the reference voltage transistor may be a dual gate transistor having two gate electrodes and two channel regions.

Similarly, in an embodiment, since the second semiconductor layer ACT2 may have a bent shape and the second-2 scan line GCL2 may have a protrusion, the second-2 scan line GCL2 may overlap the second-2 semiconductor layer ACT2 twice. Therefore, the third transistor T3 which is the compensation transistor may be a dual-gate transistor having two gate electrodes and two channel regions. In an embodiment, the third scan line GIL may overlap the second semiconductor layer ACT2 where the second semiconductor layer ACT2 is bent twice, so that the third scan line GIL may overlap the second semiconductor layer ACT2 twice. Accordingly, the fourth transistor T4 which is the first initialization transistor may also be a dual-gate transistor having two gate electrodes and two channel regions. The first gate layer GTL1 may include metal, an alloy, a conductive metal oxide, or a transparent conductive material and the like. As an example, in an embodiment the first gate layer GTL1 may include silver (Ag), an alloy containing silver, molybdenum (Mo), an alloy containing molybdenum, aluminum (Al), an alloy containing aluminum, aluminum nitride (AlN), and tungsten (W) , tungsten nitride (WN), copper (Cu), nickel (Ni), chrome (Cr), chrome nitride (CrN), titanium (Ti), tantalum (Ta), platinum (Pt), scandium (Sc), indium tin oxide (ITO) or indium zinc oxide (IZO), and the like. The first gate layer GTL1 may have a multi-layered structure. For example, in an embodiment the first gate layer GTL1 may have a two-layered structure of Mo/Al or a three-layered structure of Mo/Al/Mo.

A second gate insulating layer 105 (see FIG. 17) may cover the first gate layer GTL1 and be disposed on the first gate insulating layer 103. The second gate insulating layer 105 may include an insulating material the same as or similar to an insulating material of the first gate insulating layer 103.

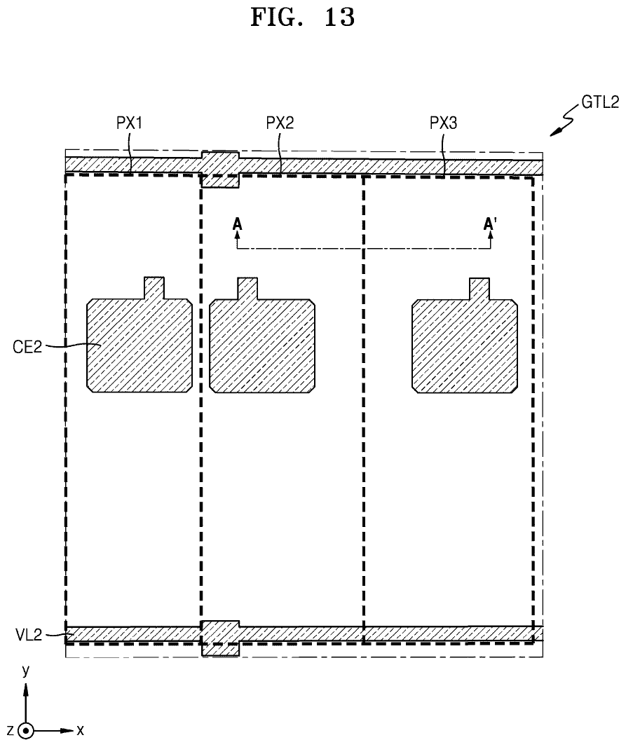

A second gate layer GTL2 shown in FIG. 13 may be disposed on the second gate insulating layer 105 (e.g., in the z-axis direction). In an embodiment, the second gate layer GTL2 may include the second-2 initialization voltage line VL2 and a second capacitor electrode CE2. In an embodiment, the second-2 initialization voltage line VL2, which is a part of the second initialization voltage line VL, may extend approximately in the first direction (e.g., the x-axis direction) and may be integrally formed as a single unitary indivisible body throughout a plurality of pixels. The second-2 initialization voltage line VL2 may be electrically connected to the seventh transistor T7 in the second pixel PX2 to transmit the second initialization voltage VAINT to the seventh transistor T7 in the second pixel PX2. In an embodiment, the second capacitor electrode CE2 may have an isolated shape. The second capacitor electrode CE2 may overlap the first capacitor electrode CE1 in the plan view. The first capacitor electrode CE1 and the second capacitor electrode CE2 may form the holding capacitor Chold. For example, the second capacitor electrode CE2 may be the second electrode of the holding capacitor Chold. At the same time, the second capacitor electrode CE2 may also function as the first electrode of the storage capacitor Cst.

The second gate layer GTL2 may include metal, an alloy, a conductive metal oxide, or a transparent conductive material and the like. As an example, in an embodiment the second gate layer GTL2 may include silver (Ag), an alloy containing silver, molybdenum (Mo), an alloy containing molybdenum, aluminum (Al), an alloy containing aluminum, aluminum nitride (AlN), and tungsten (W) , tungsten nitride (WN), copper (Cu), nickel (Ni), chrome (Cr), chrome nitride (CrN), titanium (Ti), tantalum (Ta), platinum (Pt), scandium (Sc), indium tin oxide (ITO) or indium zinc oxide (IZO), and the like. The second gate layer GTL2 may have a multi-layered structure. For example, in an embodiment the second gate layer GTL2 may have a two-layered structure of Mo/Al or a three-layered structure of Mo/Al/Mo.

A third gate insulating layer 107 (FIG. 17) may cover the second gate layer GTL2 and may be disposed on (e.g., disposed directly thereon) the second gate insulating layer 105. The third gate insulating layer 107 may include an insulating material the same as or similar to an insulating material of the second gate insulating layer 105.

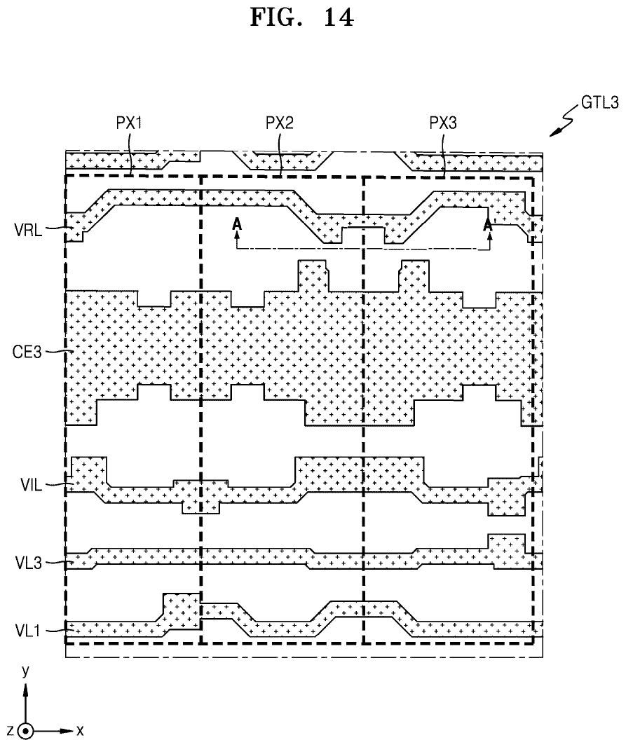

A third gate layer GTL3 shown in FIG. 14 may be disposed on the third gate insulating layer 107 (e.g., in the z-axis direction). In an embodiment, the third gate layer GTL3 may include the reference voltage line VRL, the first initialization voltage line VIL, the second-1 initialization voltage line VL1, the second-3 initialization voltage line VL3, and the third capacitor electrode CE3. In an embodiment, each of the reference voltage line VRL, the first initialization voltage line VIL, the second-1 initialization voltage line VL1, the second-3 initialization voltage line VL3, and the third capacitor electrode CE3 may extend approximately in the first direction (e.g., the x-axis direction) and may be integrally formed as a single unitary indivisible body throughout a plurality of pixels. The reference voltage line VRL may transmit the reference voltage VREF to the fifth transistor T5, which is the reference voltage transistor. The first initialization voltage line VIL may transmit the initialization voltage VINT to the gate electrode of the first transistor T1, which is the driving transistor, through the fourth transistor T4 which is the first initialization transistor. The second-1 initialization voltage line VL1 may transmit the second initialization voltage VAINT to the first pixel electrode through the seventh transistor T7 in the first pixel PX1. The second-3 initialization voltage line VL3 may transmit the second initialization voltage VAINT to the seventh transistor T7 in the third pixel PX3. The third capacitor electrode CE3 may overlap the second capacitor electrode CE2 in the plan view. In an embodiment, the second capacitor electrode CE2 and the third capacitor electrode CE3 may form the storage capacitor Cst. For example, the third capacitor electrode CE3 may function as the second electrode of the storage capacitor Cst.

The third gate layer GTL3 may include metal, an alloy, a conductive metal oxide, or a transparent conductive material and the like. As an example, in an embodiment the third gate layer GTL3 may include silver (Ag), an alloy containing silver, molybdenum (Mo), an alloy containing molybdenum, aluminum (Al), an alloy containing aluminum, aluminum nitride (AlN), and tungsten (W) , tungsten nitride (WN), copper (Cu), nickel (Ni), chrome (Cr), chrome nitride (CrN), titanium (Ti), tantalum (Ta), platinum (Pt), scandium (Sc), indium tin oxide (ITO) or indium zinc oxide (IZO), and the like. The third gate layer GTL3 may have a multi-layered structure. For example, in an embodiment the third gate layer GTL3 may have a two-layered structure of Mo/Al or a three-layered structure of Mo/Al/Mo.

A first interlayer insulating layer 109 (see FIG. 17) may cover the third gate layer GTL3 and be disposed on (e.g., disposed directly thereon) the third gate insulating layer 107. The first interlayer insulating layer 109 may include an insulating material. For example, in an embodiment the first interlayer insulating layer 109 may include silicon oxide, silicon nitride, silicon oxynitride, or aluminum oxide.

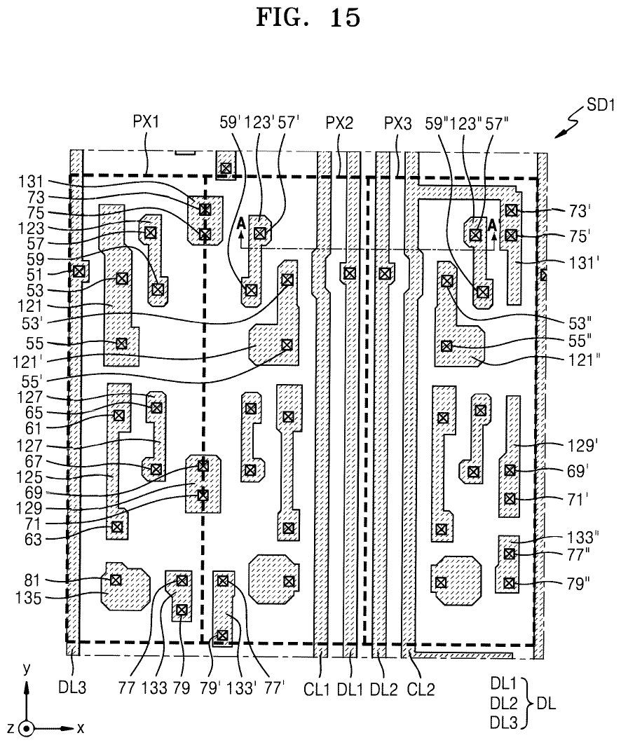

A first source-drain layer SD1 shown in FIG. 15 may be disposed on the first interlayer insulating layer 109 (e.g., disposed directly thereon in the z-axis direction). In an embodiment, the first source-drain layer SD1 may include the data line DL, a first common line CL1, a second common line CL2, and connection electrodes 121, 123, 125, 127, 129, 131, 133, and 135. In an embodiment, the data line DL may include the first data line DL1, the second data line DL2, and the third data line DL3 as described above. In a embodiment, each of the first data line DL1, the second data line DL2, the third data line DL3, the first common line CL1, and the second common line CL2 may extend approximately in the second direction (e.g., the y-axis direction) and may be integrally formed as a single unitary indivisible body throughout a plurality of pixels. In an embodiment, the connection electrodes 121′, 123′, and 133′ corresponding to the connection electrodes 121, 123 and 133 in the first pixel PX1 may be located in the second pixel PX2, and the connection electrodes 121″, 123″, 129′, 131′, and 133″ corresponding to the connection electrodes 121, 123, 129, 131 and 133 in the first pixel PX1 may be located in the third pixel PX3. The connection electrodes 131 and 129 may be located across the first pixel PX1 and the second pixel PX2, so that the connection electrodes 131 and 129 may perform the same function in the first pixel PX1 and the second pixel PX2. In an embodiment, most of the connection electrodes may have an isolated shape in the plan view.

In an embodiment, the third data line DL3 may be connected to the first semiconductor layer ACT1 through a contact hole 51 defined in insulating layers below the third data line DL3 and may transmit the data signal DATA to the first region of the second transistor T2 which is the switching transistor of the first pixel PX1. Similarly, the first data line DL1 may transmit the data signal DATA to the first region of the second transistor T2 of the second pixel PX2, and the second data line DL2 may transmit the data signal DATA to the first region of the second transistor T2 of the third pixel PX3.

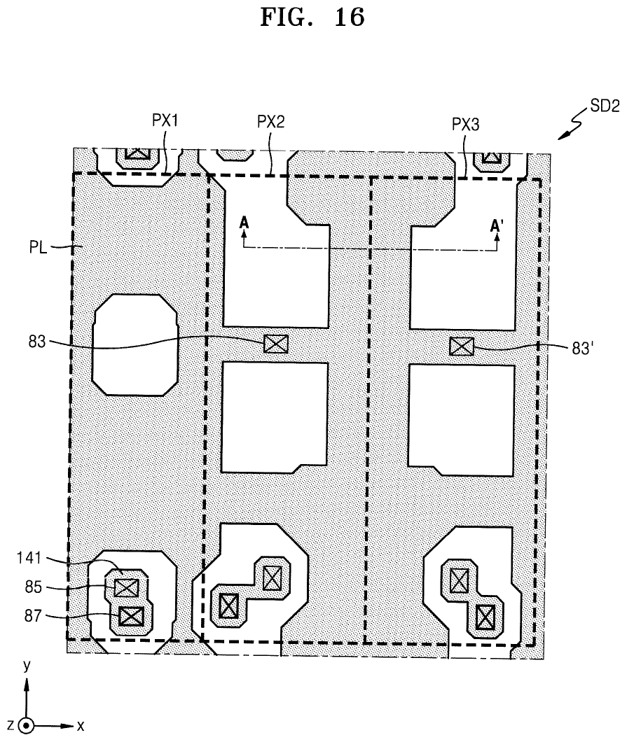

In an embodiment, in the first pixel PX1, the connection electrode 121 may be connected to the second semiconductor layer ACT2 of the first pixel PX1 through a contact hole 53 defined in the insulating layers below the connection electrode 121, and may be connected to the third capacitor electrode CE3 through a contact hole 55 defined in the insulating layer below the connection electrode 121. In the second pixel PX2, the connection electrode 121′ may be connected to the second semiconductor layer ACT2 of the second pixel PX2 through a contact hole 53′ defined in the insulating layers below the connection electrode 121′ , and may be connected to the third capacitor electrode CE3 through a contact hole 55′ defined in the insulating layer below the connection electrode 121′. In the third pixel PX3, the connection electrode 121″ may be connected to the second semiconductor layer ACT2 of the third pixel PX3 through a contact hole 53″ defined in the insulating layers below the connection electrode 121″, and may be connected to the third capacitor electrode CE3 through a contact hole 55″ defined in the insulating layer below the connection electrode 121″. Each of the connection electrode 121′ of the second pixel PX2 and the connection electrode 121″ of the third pixel PX3 may be connected to the power line PL (see FIG. 16) above the connection electrode 121′ and the connection electrode 121″, as described below. Accordingly, the driving voltage ELVDD from the power line PL may be applied to the connection electrode 121, the connection electrode 121′, the connection electrode 121″, and the third capacitor electrode CE3, and the driving voltage ELVDD may also be applied to the first region of the first transistor T1, which is the driving transistor, in each of the first pixel PX1, the second pixel PX2, and the third pixel PX3.

In an embodiment, in the first pixel PX1, the connection electrode 123 may be connected to the second semiconductor layer ACT2 of the first pixel PX1 through a contact hole 57 defined in the insulating layers below the connection electrode 123, and may be connected to the second capacitor electrode CE2 through a contact hole 59 defined in the insulating layers below the connection electrode 123, so that the second region of the second transistor T2, which is the switching transistor of the first pixel PX1, may be electrically connected to the second electrode of the holding capacitor Chold of the first pixel PX1. In the second pixel PX2, the connection electrode 123′ may be connected to the second semiconductor layer ACT2 of the second pixel PX2 through a contact hole 57′ defined in the insulating layers below the connection electrode 123′, and may be connected to the second capacitor electrode CE2 of the second pixel PX2 through a contact hole 59′ defined in the insulating layers below the connection electrode 123′, so that the second region of the second transistor T2, which is the switching transistor of the second pixel PX2, may be electrically connected to the second electrode of the holding capacitor Chold of the second pixel PX2. In the third pixel PX3, the connection electrode 123″ may be connected to the second semiconductor layer ACT2 of the third pixel PX3 through the contact hole 57″ defined in the insulating layers below the connection electrode 123″, and may be connected to the second capacitor electrode CE2 of the third pixel PX3 through the contact hole 59″ defined in the insulating layers below the connection electrode 123″, so that the second region of the second transistor T2, which is the switching transistor of the third pixel PX3, may be electrically connected to the second electrode of the holding capacitor Chold of the third pixel PX3. In this embodiment, the connection electrode 123 may be the first node N1 in the first pixel PX1, the connection electrode 123′ may be the first node N1 in the second pixel PX2, and the connection electrode 123″ may be the first node N1 in the third pixel PX3.

In an embodiment, in the first pixel PX1, the connection electrode 125 may be connected to the second semiconductor layer ACT2 of the first pixel PX1 through a contact hole 61 defined in the insulating layers below the connection electrode 125, and may be connected to the third semiconductor layer ACT3 of the first pixel PX1 through a contact hole 63 defined in the insulating layers below the connection electrode 125, so that the second region of the first transistor T1, which is the driving transistor of the first pixel PX1, may be electrically connected to the first region of the sixth transistor T6, which is the emission control transistor of the first pixel PX1. This may also apply to the second pixel PX2 and the third pixel PX3.

In an embodiment, in the first pixel PX1, the connection electrode 127 may be connected to the first capacitor electrode CE1 of the first pixel PX1 through a contact hole 65 defined in the insulating layers below the connection electrode 127, and may be connected to the second semiconductor layer ACT2 of the first pixel PX1 through a contact hole 67 defined in the insulating layers below the connection electrode 127, so that the gate electrode of the first transistor T1, which is the driving transistor of the first pixel PX1, may be electrically connected to the second region of the third transistor T3, which is the compensation transistor of the first pixel PX1. In this embodiment, the connection electrode 127 may be the second node N2 in the first pixel PX1. This may also apply to the second pixel PX2 and the third pixel PX3.

A connection electrode 129 located across the first pixel PX1 and the second pixel PX2 may be connected to the second semiconductor layer ACT2, which is integrally formed as a single unitary indivisible body in the first and second pixels PX1 and PX2, through a contact hole 69 defined in the insulating layers below the connection electrode 127, and may be connected to the first initialization voltage line VIL through a contact hole 71 defined in the insulating layer below the connection electrode 127, so that the initialization voltage VINT from the first initialization voltage line VIL may be transmitted to the first region of the fourth transistor T4 which is the first initialization transistor of the first pixel PX1 and the first region of the fourth transistor T4 which is the first initialization transistor of the second pixel PX2. Similarly, the connection electrode 129′ in the third pixel PX3 may be connected to the second semiconductor layer ACT2 of the third pixel PX3 through a contact hole 69′ defined in the insulating layers below the connection electrode 129′, and may be connected to the first initialization voltage line VIL through a contact hole 71′ defined in the insulating layer below the connection electrode 129′, so that the initialization voltage VINT from the first initialization voltage line VIL may be transmitted to the first region of the fourth transistor T4, which is the first initialization transistor of the third pixel PX3.

In an embodiment, the connection electrode 131 across the first pixel PX1 and the second pixel PX2 may be connected to the first semiconductor layer ACT1 which is integrally formed as a single unitary indivisible body across the first and second pixels PX1 and PX2 through a contact hole 75 defined in the insulating layers below the connection electrode 131, and may be connected to the reference voltage line VRL through a contact hole 73 defined in the insulating layer below the connection electrode 131, so that the reference voltage VREF from the reference voltage line VRL may be transmitted to the first region of the fifth transistor T5 which is the reference voltage transistor of the first pixel PX1 and the first region of the fifth transistor T5 which is the reference voltage transistor of the second pixel PX2. Similarly, the connection electrode 131′ in the third pixel PX3 may be connected to the first semiconductor layer ACT1 of the third pixel PX3 through a contact hole 75′ defined in the insulating layers below the connection electrode 131′, and may be connected to the reference voltage line VRL through a contact hole 73′ defined in the insulating layer below the connection electrode 131′, so that the reference voltage VREF from the reference voltage line VRL may be transmitted to the first region of the fifth transistor T5, which is the reference voltage transistor of the third pixel PX3. In an embodiment, the connection electrode 131′ in the third pixel PX3 and the second common line CL2 may be integrally formed as a single unitary indivisible body as described below.

In an embodiment, in the first pixel PX1, the connection electrode 133 may be connected to the third semiconductor layer ACT3 of the first pixel PX1 through a contact hole 77 defined in the insulating layers below the connection electrode 133, and may be connected to the second-1 initialization voltage line VL1 through a contact hole 79 defined in the insulating layer below the connection electrode 133, so that the second initialization voltage VAINT from the second-1 initialization voltage line VL1 may be transmitted to the first region of the seventh transistor T7, which is the second initialization transistor of the first pixel PX1. In the second pixel PX2, the connection electrode 133′ may be connected to the third semiconductor layer ACT3 of the second pixel PX2 through a contact hole 77′ defined in the insulating layers below the connection electrode 133′, and may be connected to the second-2 initialization voltage line VL2 through a contact hole 79′ defined in the insulating layers below the connection electrode 133′, so that the second initialization voltage VAINT from the second-2 initialization voltage line VL2 may be transmitted to the first region of the seventh transistor T7, which is the second initialization transistor of the second pixel PX2. In the third pixel PX3, the connection electrode 133″ may be connected to the third semiconductor layer ACT3 of the third pixel PX3 through the contact hole 77″ defined in the insulating layers below the connection electrode 133″, and may be connected to the second-3 initialization voltage line VL3 through the contact hole 79″ defined in the insulating layer below the connection electrode 133″, so that the second initialization voltage VAINT from the second-3 initialization voltage line VL3 may be transmitted to the first region of the seventh transistor T7, which is the second initialization transistor of the third pixel PX3.

In an embodiment, in the first pixel PX1, the connection electrode 135 may be connected to the third semiconductor layer ACT3 of the first pixel PX1 through a contact hole 81 defined in the insulating layers below the connection electrode 135. For example, the second region of the sixth transistor T6, which is the emission control transistor of the first pixel PX1, and the second region of the seventh transistor T7, which is the second initialization transistor, may be electrically connected to each other through the connection electrode 135. As described later, the connection electrode 135 may be electrically connected to the pixel electrode PE1 (see FIG. 17) of the organic light-emitting diode OLED of the first pixel PX1 through an upper connection electrode 141. This may also apply to the second pixel PX2 and the third pixel PX3.

As shown in FIG. 15, in an embodiment the first data line DL1 and the second data line DL2 may be arranged along the first direction (e.g., the x-axis direction). In an embodiment, in the second pixel PX2, the second transistor T2, which may be referred to as the first switching transistor, may receive the data signal (e.g., a first data signal) from the first data line DL1 in the first region in response to the first scan signal and may transmit it to the first node N1 of the second pixel PX2, which may be referred to as a first switching node, through the second region. The first node N1 in the second pixel PX2 may be the connection electrode 123′ as described above. The connection electrode 123′ may be located in a direction (e.g., the-x direction) further away from the second data line DL2 with respect to the first data line DL1.

The first common line CL1 may be located between the connection electrode 123′, which is the first switching node of the second pixel PX2, and the first data line DL1 (e.g., in the x-axis direction), and may extend approximately in the second direction (e.g., the y-axis direction) like the first data line DL1. A first constant voltage may be applied to the first common line CL1. In an embodiment, the first constant voltage may be, for example, the first initialization voltage VINT transmitted by the first initialization voltage line VIL, the second initialization voltage VAINT transmitted by the second initialization voltage line VL, the driving voltage ELVDD transmitted by the power line PL, the reference voltage VREF transmitted by the reference voltage line VRL, or the common voltage ELVSS applied to the common electrode CME (see FIG. 17) of the organic light emitting diode OLED. To this end, the first common line CL1 may be electrically connected to the first initialization voltage line VIL, the second-1 initialization voltage line VL1, the second-2 initialization voltage line VL2, the second-3 initialization voltage line VL3, the power line PL, the reference voltage line VRL, or the common electrode CME through a contact hole below or above the first common line CL1, in a row other than the row shown in FIG. 15.

Alternatively, in an embodiment the first common line CL1 may be integral with one of the connection electrodes which has a constant electric potential (e.g., a constant voltage), in the second pixel PX2. For example, in an embodiment the connection electrode 121′ of the second pixel PX2 may be connected to the power line PL above the connection electrode 121′ as described below, and the first common line CL1 and the connection electrode 121′ of the second pixel PX2 may be integrally formed as a single unitary indivisible body, so that the electric potential of the first common line CL1 may be the driving voltage ELVDD. Alternatively, in an embodiment the connection electrode 131 of the second pixel PX2 may be connected to the reference voltage line VRL as described above, and the first common line CL1 and the connection electrode 131 may be integrally formed as a single unitary indivisible body, so that the electric potential of the first common line CL1 may be the reference voltage VREF.

As described above, in an embodiment in the second pixel PX2, the second transistor T2, which is the first switching transistor, may receive the data signal (e.g., the first data signal) from the first data line DL1 in the first region in response to the first scan signal and may transmit it to the first node N1 of the second pixel PX2, which may be referred to as the first switching node, through the second region. The first node N1 in the second pixel PX2 may be the connection electrode 123′ as described above. The electric potential of the first node N1 may be an electric potential related to the brightness of light to be emitted from the organic light-emitting diode OLED, which is the display element of the second pixel PX2. Therefore, it is necessary to minimize external influence on the electric potential of the first node N1 during the emission period.

The first data line DL1 passing through the second pixel PX2 not only transmits the data signal to the second pixel PX2 in the same row as shown in FIG. 15, but also transmits the data signal to pixels located in other rows of the same column during the emission period of the second pixel PX2. Therefore, if the electric potential of the first node N1 is electrically affected by the first data line DL1 which transmits the data signal to pixels located in other rows of the same column during the emission period of the second pixel PX2, the brightness of light emitted from the organic light-emitting diode OLED, which is the display element of the second pixel PX2, may be different from the brightness which is originally intended. This may cause a deterioration in the quality of images displayed by the display panel 10.

However, in the display panel 10 according to an embodiment described above and the electronic apparatus 1 including the display panel 10, the first common line CL1 to which a constant voltage is applied may be located between (e.g., in the x-axis direction) the connection electrode 123′, which is the first switching node of the second pixel PX2, and the first data line DL1, and may extend approximately in the second direction (e.g., the y-axis direction) like the first data line DL1. Accordingly, it is possible to prevent or minimize the electrical influence on the connection electrode 123′, which is the first switching node of the second pixel PX2, from the first data line DL1, during the emission period of the second pixel PX2. Accordingly, the display panel 10 displaying high-quality images, and the electronic apparatus 1 including the same may be implemented.

As described above, in an embodiment each of sets may include the first pixel PX1, the second pixel PX2, and the third pixel PX3, and the sets may be repeatedly arranged in the first direction (e.g., the x-axis direction). Accordingly, the first common line CL1 passing through the second pixel PX2 of the column shown in FIG. 15 may be electrically connected to the first initialization voltage line VIL so that the electric potential of the first common line CL1 may be the first initialization voltage VINT, the first common line CL1 passing through the second pixel PX2 of another column may be electrically connected to the power line PL so that the electric potential of the first common line CL1 may be the driving voltage ELVDD, and the first common line CL1 passing through the second pixel PX2 of another column may be electrically connected to the common electrode CME of the organic light-emitting diode OLED so that the electric potential of the first common line CL1 may be the common voltage ELVSS.

In an embodiment, in the third pixel PX3, as shown in FIG. 15, the second transistor T2, which may be referred to as the second switching transistor, may receive the data signal (e.g., a second data signal) from the second data line DL2 in the first region in response to the first scan signal and may transmit it to the first node N1 of the third pixel PX3, which may be referred to as the second switching node, through the second region. The first node N1 in the third pixel PX3 may be the connection electrode 123″ as described above. In an embodiment, the connection electrode 123″ may be located in a direction (e.g., a +x direction) further away from the first data line DL1 with respect to the second data line DL2.

The second common line CL2 may located between (e.g., in the x-axis direction) the connection electrode 123″, which is the second switching node of the third pixel PX3, and the second data line DL2, and may extend approximately in the second direction (y-axis direction). A second constant voltage may be applied to the second common line CL2. FIG. 15 shows an embodiment in which the second common line CL2 and the connection electrode 131′ of the third pixel PX3 are integrally formed as a single unitary indivisible body, and thus the second common line CL2 is electrically connected to the reference voltage line VRL through the connection electrode 131′. In this embodiment, the reference voltage VREF may be applied to the second common line CL2.

In an embodiment, the second constant voltage may be, for example, the first initialization voltage VINT transmitted by the first initialization voltage line VIL, the second initialization voltage VAINT transmitted by the second initialization voltage line VL, the driving voltage ELVDD transmitted by the power line PL, the reference voltage VREF transmitted by the reference voltage line VRL, or the common voltage ELVSS applied to the common electrode CME of the organic light emitting diode OLED. In this embodiment, unlike the case shown in FIG. 15, the second common line CL2 may be spaced apart from the connection electrode 131′ of the third pixel PX3, and may be electrically connected to one of the first initialization voltage line VIL, the second-1 initialization voltage line VL1, the second-2 initialization voltage line VL2, the second-3 initialization voltage line VL3, the power line PL, or the common electrode CME through a contact hole disposed below or above the second common line CL2.

Alternatively, the second common line CL2 may be integral with one of the connection electrodes which has a constant electric potential (e.g., a constant voltage), in the third pixel PX3. FIG. 15 shows an embodiment in which the second common line CL2 and the connection electrode 131′ of the third pixel PX3 are integrally formed as a single unitary indivisible body, as described above. Of course, one or more embodiments are not necessarily limited thereto. For example, in an embodiment, the connection electrode 121″ of the third pixel PX3 may be connected to the power line PL above the connection electrode 121″ as described below, and the second common line CL2 and the connection electrode 121″ of the third pixel PX3 may be integrally formed as a single unitary indivisible body, so that the electric potential of the second common line CL2 may be the driving voltage ELVDD.

In the case of the display panel 10 according to an embodiment described above and the electronic apparatus 1 including the display panel 10, the second common line CL2 to which a constant voltage is applied may be located between (e.g., in the x-axis direction) the connection electrode 123″, which is the second switching node of the third pixel PX3, and the second data line DL2, and may extend approximately in the second direction (y-axis direction) like the second data line DL2. Accordingly, it is possible to prevent or minimize the electrical influence on the connection electrode 123″, which is the second switching node of the third pixel PX3, from the second data line DL2, during the emission period of the third pixel PX3. Accordingly, the display panel 10 displaying high-quality images, and the electronic apparatus 1 including the same may be implemented.

In an embodiment, a level of the first constant voltage applied to the first common line CL1 may be different from a level of the second constant voltage applied to the second common line CL2. For example, in an embodiment the first constant voltage applied to the first common line CL1 may be the driving voltage ELVDD, and the second constant voltage applied to the second common line CL2 may be the reference voltage VREF.

As described above, each of sets may include the first pixel PX1, the second pixel PX2, and the third pixel PX3, and the sets may be repeatedly arranged in the first direction (e.g., the x-axis direction). Accordingly, the first pixel PX1 may be located adjacent to the third pixel PX3 in the +x direction of the third pixel PX3, and thus the third data line DL3 passing through the first pixel PX1 may be located in the +x direction of the third pixel PX3. It is necessary to prevent or minimize the influence on the connection electrode 123″, which is the second switching node of the third pixel PX3, from the third data line DL3 located in the +x direction of the third pixel PX3.

In the case of the display panel 10 according to an embodiment described above and the electronic apparatus 1 including the display panel 10, the connection electrode 131′ of the third pixel PX3 may be located between (e.g., in the x-axis direction) the connection electrode 123″, which is the second switching node of the third pixel PX3, and the third data line DL3 located in the +x direction of the third pixel PX3. In an embodiment, the connection electrode 131′ of the third pixel PX3 may be electrically connected to the reference voltage line VRL by a contact hole 73′ defined in the insulating layer below the connection electrode 131′. Therefore, the reference voltage VREF, which is a constant voltage, may be applied to the connection electrode 131′ of the third pixel PX3. The connection electrode 131′ of the third pixel PX3 may prevent or minimize the connection electrode 123″, which is the second switching node of the third pixel PX3, from being affected by the third data line DL3 located in the +x direction of the third pixel PX3.

In an embodiment, the connection electrode 131′ of the third pixel PX3 may have a shape slightly extended in the second direction (e.g., the y-axis direction) like the connection electrode 123″, which is the second switching node, and a length of the connection electrode 131′ of the third pixel PX3 in the second direction (e.g., the y-axis direction) may be greater than a length of the connection electrode 123″, which is the second switching node of the third pixel PX3, in the second direction (e.g., the y-axis direction).

In an embodiment, as shown in FIG. 15, the third data line DL3 passing through the first pixel PX1 may be located in the direction (e.g., the-x direction) further away from the first data line DL1 passing through the second pixel PX2 with respect to the connection electrode 123, which is the first switching node of the first pixel PX1, and may extend in the second direction (e.g., the y-axis direction). In an embodiment, in the first pixel PX1, the second transistor T2, which may be referred to as the third switching transistor, may receive the data signal (e.g., the third data signal) from the third data line DL3 in the first region in response to the first scan signal and may transmit it to the first node N1 of the first pixel PX1, which may be referred to as the third switching node, through the second region. The first node N1 in the first pixel PX1 may be the connection electrode 123 as described above. The connection electrode 123, which is the third switching node, may be located between (e.g., in the x-axis direction) the connection electrode 123′ of the second pixel PX2, which may be referred to as the first switching node, and the third data line DL3, as described above. At this time, the prevention or minimization of the connection electrode 123, which is the third switching node of the first pixel PX1, from being affected by the third data line DL3 passing through the first pixel PX1 during the emission period of the first pixel PX1 is desired.

In the case of the display panel 10 according to an embodiment described above and the electronic apparatus 1 including the display panel 10, the connection electrode 121 of the first pixel PX1 may be located between (e.g., in the x-axis direction) the connection electrode 123, which is the third switching node of the first pixel PX1, and the third data line DL3 passing through the first pixel PX1. In an embodiment, the connection electrode 121 of the first pixel PX1 may be connected to the third capacitor electrode CE3 through a contact hole 55 defined in the insulating layer below the connection electrode 121, the third capacitor electrode CE3 may be connected to the connection electrode 121′ of the second pixel PX2 through a contact hole 55′, and the connection electrode 121′ of the second pixel PX2 may be connected to the power line PL above the connection electrode 121′ through the contact hole. Therefore, the driving voltage ELVDD, which is a constant voltage, may be applied to the connection electrode 121 of the first pixel PX1. The connection electrode 121 of the first pixel PX1 may prevent or minimize the connection electrode 123, which is the third switching node of the first pixel PX1, from being affected by the third data line DL3 passing through the first pixel PX1.

In an embodiment, the connection electrode 121 of the first pixel PX1 may have a shape which is slightly extended in the second direction (e.g., the y-axis direction) like the connection electrode 123 of the third switching node, and a length of the connection electrode 121 of the first pixel PX1 in the second direction (e.g., the y-axis direction) may be greater than a length of the connection electrode 123 of the third switching node of the first pixel PX1 in the second direction (e.g., the y-axis direction).

The first source-drain layer SD1 may include metal, an alloy, a conductive metal oxide, or a transparent conductive material and the like. As an example, in an embodiment the first source-drain layer SD1 may include silver (Ag), an alloy containing silver, molybdenum (Mo), an alloy containing molybdenum, aluminum (Al), an alloy containing aluminum, aluminum nitride (AlN), and tungsten (W) , tungsten nitride (WN), copper (Cu), nickel (Ni), chrome (Cr), chrome nitride (CrN), titanium (Ti), tantalum (Ta), platinum (Pt), scandium (Sc), indium tin oxide (ITO) or indium zinc oxide (IZO), and the like. The first source-drain layer SD1 may have a multi-layered structure. For example, in an embodiment the first source-drain layer SD1 may have a two-layered structure of Ti/Al or a three-layered structure of Ti/Al/Ti.

For reference, the electric potential of the gate electrode of the first transistor T1 which is the driving transistor of the second pixel PX2, such as the electric potential of the first capacitor electrode CE1 which is the second node N2 of the second pixel PX2, may be also an electric potential related to the brightness of light to be emitted from the organic light-emitting diode OLED which is the display element of the second pixel PX2. Similarly, the electric potential of the gate electrode of the first transistor T1 which is the driving transistor of the third pixel PX3, such as the electric potential of the first capacitor electrode CE1 which is the second node N2 of the third pixel PX3, may be also an electric potential related to the brightness of light to be emitted from the organic light-emitting diode OLED which is the display element of the third pixel PX3. Therefore, during the emission period of the second pixel PX2, prevention or minimization of the influence on the gate electrode of the first transistor T1 of the second pixel PX2 from being affected by a portion P1 (see FIG. 11) which is a part of the second semiconductor layer ACT2 of the second pixel PX2 and connected to the first data line DL1 passing through the second pixel PX2 through the contact hole 51 is desired. Similarly, during the emission period of the third pixel PX3, prevention or minimization of the influence on the gate electrode of the first transistor T1 of the third pixel PX3 from being affected by a portion P2 (see FIG. 11) which is a part of the second semiconductor layer ACT2 of the third pixel PX3 and connected to the second data line DL2 passing through the third pixel PX3 through the contact hole 51 is desired.

In the case of the display panel 10 according to an embodiment described above and the electronic apparatus 1 including the display panel 10, as described above, the second semiconductor layer ACT2 of the second pixel PX2 and the second semiconductor layer ACT2 of the third pixel PX3 may be integrally formed as a single unitary indivisible body. Accordingly, the second semiconductor layer ACT2 may have a portion B (see FIG. 11) crossing the boundary between the second pixel PX2 and the third pixel PX3. In an embodiment, the second semiconductor layer ACT2 may be electrically connected to the power line PL through the connection electrode 121′ on one side of the portion B (e.g., in a-x direction), and may be electrically connected to the power line PL through the connection electrode 121″ on the other side of the portion B (e.g., in a +x direction). Therefore, the portion B of the second semiconductor layer ACT2 crossing the boundary between the second pixel PX2 and the third pixel PX3 may have a constant voltage (e.g., a constant electric potential) corresponding to the driving voltage ELVDD. Accordingly, the portion B of the second semiconductor layer ACT2 crossing the boundary between the second pixel PX2 and the third pixel PX3 may reduce the influence on the gate electrodes of the first transistors T1 of the second and third pixels PX2 and PX3 from the portions P1 and P2 which are connected to the first and second data lines DL1 and DL2 by the contact holes 51 and which are parts of the second semiconductor layer ACT2 of the second pixel PX2 and the third pixel PX3, during the emission period of the second and third pixels PX2 and PX3. For example, in the plan view, the portion B of the second semiconductor layer ACT2 crossing the boundary between the second pixel PX2 and the third pixel PX3 is located between the first capacitor electrodes CE1, which are the gate electrodes of the first transistors T1 of the second and third pixels PX2 and PX3, and portions P1 and P2 of the second semiconductor layer ACT2.

A second interlayer insulating layer 111 (see FIG. 17) may cover the first source-drain layer SD1 and may be disposed on (e.g., disposed directly thereon) the first interlayer insulating layer 109. The second interlayer insulating layer 111 may include an insulating material. As an example, in an embodiment the second interlayer insulating layer 111 may include silicon oxide, silicon nitride, silicon oxynitride, or aluminum oxide.

A second source-drain layer SD2 shown in FIG. 16 may be disposed on (e.g., disposed directly thereon) the second interlayer insulating layer 111. In an embodiment, the second source-drain layer SD2 may include the power line PL transmitting the driving voltage ELVDD and having a mesh shape in the display area DA, and connection electrodes 141 in the first, second, and third pixel PX1, PX2, and PX3. The power line PL having the mesh shape in the plan view may be understood as having a plurality of holes as shown in FIG. 16. The connection electrodes 141 may be located within the plurality of holes.

In an embodiment, the power line PL may be connected to the connection electrode 121′ of the second pixel PX2 through a contact hole 83 defined in the insulating layer below the power line PL, and may be connected to the connection electrode 121″ of the third pixel PX3 through a contact hole 83′ defined in the insulating layer below the power line PL.

In an embodiment, the connection electrode 141 of the first pixel PX1 may be connected to the connection electrode 135 through a contact hole 85 defined in the insulating layer below the connection electrode 141. In an embodiment, the connection electrode 141 of the first pixel PX1 may be connected to the first pixel electrode of the organic light-emitting device OLED of the first pixel PX1 through a contact hole 87 defined in the insulating layer above the connection electrode 141. As described above, the connection electrode 135 of the first pixel PX1 may be connected to the second region of the sixth transistor T6 and the second region of the seventh transistor T7, so that the first pixel electrode of the organic light-emitting device OLED of the first pixel PX1 may be electrically connected to the second region of the sixth transistor T6 and the second region of the seventh transistor T7 of the first pixel PX1. Similarly, the second pixel electrode PE2 (see FIG. 17) of the second pixel PX2 may be electrically connected to the second region of the sixth transistor T6 and the second region of the seventh transistor T7 of the second pixel PX2, and the third pixel electrode PE3 (see FIG. 17) of the third pixel PX3 may be electrically connected to the second region of the sixth transistor T6 and the second region of the seventh transistor T7 of the third pixel PX3.

The second source-drain layer SD2 may include metal, an alloy, a conductive metal oxide, or a transparent conductive material and the like. As an example, in an embodiment the second source-drain layer SD2 may include silver (Ag), an alloy containing silver, molybdenum (Mo), an alloy containing molybdenum, aluminum (Al), an alloy containing aluminum, aluminum nitride (AlN), and tungsten (W) , tungsten nitride (WN), copper (Cu), nickel (Ni), chrome (Cr), chrome nitride (CrN), titanium (Ti), tantalum (Ta), platinum (Pt), scandium (Sc), indium tin oxide (ITO) or indium zinc oxide (IZO), and the like. The second source-drain layer SD2 may have a multi-layered structure. For example, in an embodiment the second source-drain layer SD2 may have a two-layered structure of Ti/Al or a three-layered structure of Ti/Al/Ti.

A planarization layer may cover the second source-drain layer SD2 and be disposed on (e.g., disposed directly thereon) the second interlayer insulating layer 111. The planarization layer 115 may include an organic insulating material. For example, in an embodiment the planarization layer 115 may include a photoresist, benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof. An upper surface of the planarization layer 115 may be approximately flat (e.g., planarized).

The first pixel electrode of the organic light-emitting device OLED of the first pixel PX1, the second pixel electrode PE2 of the organic light-emitting device OLED of the second pixel PX2, and the third pixel electrode PE3 of the organic light-emitting device OLED of the third pixel PX3 may be disposed on the planarization layer 115 (e.g., disposed directly thereon in the z-axis direction). FIG. 17 shows a portion of the second pixel electrode PE2 and a portion of the third pixel electrode PE3. As described above, in an embodiment the first pixel electrode may be connected to the connection electrode 141 of the first pixel PX1 through the contact hole 87 defined in the insulating layer below the first pixel electrode. This may also apply to the second pixel electrode PE2 and the third pixel electrode PE3.

The first pixel electrode, the second pixel electrode PE2, and the third pixel electrode PE3 may be a (semi) light-transmissive conductive layer or a reflective conductive layer. For example, in an embodiment each of the first pixel electrode, the second pixel electrode PE2, and the third pixel electrode PE3 may include a reflective layer and a transparent or semi-transparent electrode layer on the reflective layer, and the reflective layer may include Ag, Mg, Al, Pt, Pd, Au, Ni, Nd, Ir, Cr, or compound thereof. The transparent or semitransparent electrode layer may include at least one selected from the group consisting of indium tin oxide (ITO), indium zinc oxide (IZO), zinc oxide (ZnOx: ZnO or ZnO₂), indium oxide (In₂O₃), indium gallium oxide (IGO), and aluminum zinc oxide (AZO). For example, each of the first pixel electrode, the second pixel electrode PE2, and the third pixel electrode PE3 may have a three-layered structure of ITO/Ag/ITO.

A pixel-defining layer 119 may be disposed on (e.g., disposed directly thereon) the planarization layer 115 to cover the edge of each of the first pixel electrode, the second pixel electrode PE2, and the third pixel electrode PE3. The pixel-defining layer 119 may define a pixel by including an opening corresponding to an emission area of each pixel. For example, in an embodiment the opening of the pixel-defining layer 119 may expose a central portion (e.g., in a plan view) of the first pixel electrode, the second pixel electrode PE2 and the third pixel electrode PE3. An emission layer may be disposed in the opening of the pixel-defining layer 119, and the common electrode CME may be disposed over the emission layer. The first pixel electrode, the second pixel electrode PE2, the third pixel electrode PE3, the emission layer, and the common electrode CME may configure organic light-emitting diodes. In an embodiment, the common electrode CME may be integrally formed (e.g., commonly disposed) as a single unitary indivisible body throughout the plurality of organic light-emitting diodes to correspond to the plurality of pixel electrodes in the display area DA.

A first intermediate layer may be interposed between the first pixel electrode and the common electrode CME (e.g., in the z-axis direction), a second intermediate layer IML2 may be interposed between the second pixel electrode PE2 and the common electrode CME (e.g., in the z-axis direction), and a third intermediate layer IML3 may be interposed between the third pixel electrode PE3 and the common electrode CME (e.g., in the z-axis direction). Each of the first intermediate layer, the second intermediate layer IML2, and the third intermediate layer IML3 may include an emission layer, and the emission layer may have an isolated shape overlapping the corresponding pixel electrode. In an embodiment, each of layers other than the emission layer included in the first intermediate layer, the second intermediate layer IML2, and the third intermediate layer IML3, such as a hole transport layer, an electron transport layer, and/or an electron injection layer, may be integrally formed (e.g., commonly disposed) as a single unitary indivisible body throughout the plurality of organic light-emitting diodes OLEDs and may correspond to the plurality of pixel electrodes.

The common electrode CME may be a light-transmissive electrode or a reflective electrode. For example, in an embodiment the common electrode CME may be a transparent or semi-transparent electrode and may include a thin metal film having a low work function. The common electrode CME may include at least one of Li, Ca, Al, Ag, Mg, or compound (e.g., LiF) thereof. In an embodiment, the common electrode CME may further include a transparent conductive oxide (TCO) layer such as ITO, indium zinc oxide (IZO), ZnO, ZnO₂, or In₂O₃, disposed on the thin metal film. The common electrode CME may be integrally formed (e.g., commonly disposed) as a single unitary indivisible body throughout the entire surface of the display area DA to cover the display area DA.

In one or more embodiments, an encapsulation layer may be disposed over the common electrode CME. In an embodiment, the encapsulation layer may include a first inorganic encapsulation layer, a second inorganic encapsulation layer, and an organic encapsulation layer therebetween.

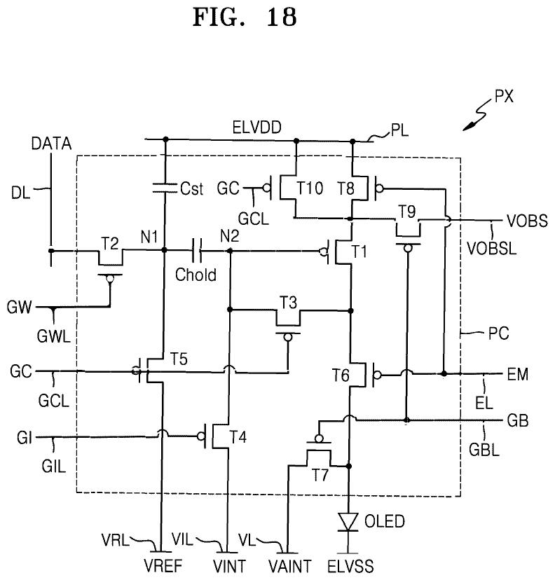

Up to this point, the description has been made to an embodiment of the display panel 10 having the pixel circuit PC shown in FIG. 8 and the electronic apparatus 1 including the display panel. However, one or more embodiments are not necessarily limited thereto. FIG. 18 shows an equivalent circuit diagram of a pixel circuit PC electrically connected to a display element included in a display module 11 according to an embodiment. As shown in FIG. 18, the pixel circuit PC may further include an eighth transistor T8, a ninth transistor T9, and a tenth transistor T10.

In an embodiment, the eighth transistor T8, which is an operation control transistor, is interposed between the first transistor T1, which is the driving transistor, and the power line PL, and is turned on in response to the emission control signal EM from the emission control line EL, so that the driving voltage ELVDD from the power line PL may be applied to the first region of the first transistor T1.

In an embodiment, the ninth transistor T9, which is a bias transistor, is turned on in response to the fourth scan signal GB from the fourth scan line GBL to apply bias voltage VOBS from a bias voltage line VOBSL to the first region of the first transistor T1, so that a voltage suitable for the subsequent operation of the first transistor T1 which is the driving transistor may be preset. Thus, the fourth scan line GBL may be referred to as a bias gate line.

In an embodiment, the tenth transistor T10 may be turned on in response to the second scan signal GC from the second scan line GCL, so that the driving voltage ELVDD from the power line PL may be applied to the first region of the first transistor T1. Therefore, the first region of the first transistor T1 may have the electric potential of the driving voltage ELVDD during the compensation period.

The above-described explanation regarding the first common line CL1 and/or the second common line CL2 may also be applied to an embodiment of the display panel 10 including the pixel circuits PC shown in FIG. 18 and the electronic apparatus 1 including the display panel 10.

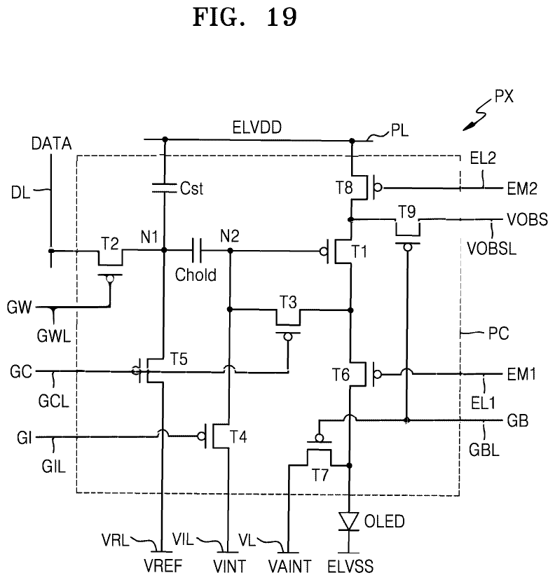

FIG. 19 shows an equivalent circuit diagram of a pixel circuit PC electrically connected to a display element included in a display module 11 according to an embodiment. As shown in FIG. 19, in an embodiment the pixel circuit PC may not include the tenth transistor T10. In addition, a first emission control signal EM1 may be applied to the gate electrode of the sixth transistor T6 through a first emission control line EL1, and a second emission control signal EM2 may be applied to the gate electrode of the eighth transistor T8 through a second emission control line EL2.

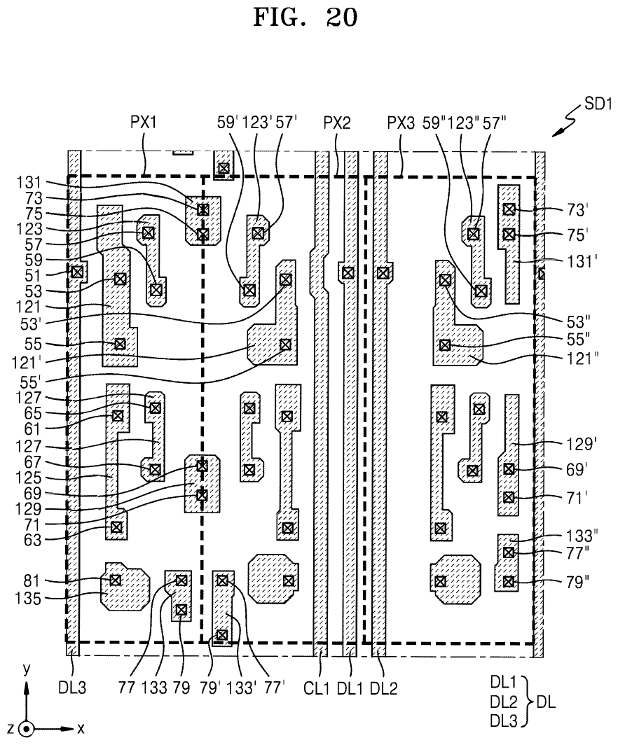

FIG. 20 is a plan view schematically illustrating one conductive layer in pixels included in a display module according to one embodiment. In an embodiment described above with reference to FIG. 15, the first source-drain layer SD1 includes the second common line CL2. However, in an embodiment shown in FIG. 20, the first source-drain layer SD1 may not include the second common line CL2. In this embodiment, it is possible to increase the area of the first common line CL1 by omitting the second common line CL2. It may be also possible to implement a high-resolution display panel 10 and an electronic apparatus 1 including the display panel 10 by omitting the second common line CL2, since the high-resolution display panel 10 needs enough space within the display area DA.

Since the second common line CL2 is omitted, the connection electrode 123″, which is the first node N1 of the third pixel PX3, may be affected by the second data line DL2 passing through the third pixel PX3. However, at least the connection electrode 123′, which is the first node N1 of the second pixel PX2, may be prevented or minimized from being affected by the first data line DL1 due to the presence of the first common line CL1. In an embodiment, a portion of the connection electrode 121″ of the third pixel PX connected to the power line PL may be extended between the second data line DL2 passing through the third pixel PX3 and the connection electrode 123″ which is the first node N1 of the third pixel PX3, so that the connection electrode 123″ which is the first node N1 of the third pixel PX3 may be prevented or minimized from being affected by the second data line DL2 passing through the third pixel PX3.

Up to this point, the description has been mainly made to the structure of the display panel 10. However, one or more embodiments are not necessarily limited thereto. The electronic apparatus 1 including such a display panel 10 may also be said to fall within the scope of the disclosure.

As described above, the present disclosure has been described with reference to the one or more non-limiting embodiments shown in the accompanying drawings, but should be considered in a descriptive sense only. Those of ordinary skill in the art will understand that various modifications and equivalent embodiments may be made therefrom.

According to an embodiment, the display panel 10 that may display high-quality images and the electronic apparatus 1 including the display panel 10 may be implemented. However, the scope of embodiments of the present disclosure are not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display panel comprising:
a first data line and a second data line arranged along a first direction, each of the first data line and the second data line extending in a second direction crossing the first direction;
a first switching transistor transmitting a first data signal from the first data line to a first switching node located in a direction further away from the second data line with respect to the first data line in response to a scan signal; and
a first common line located between the first switching node and the first data line in the first direction and extending in the second direction, wherein a first constant voltage is applied to the first common line.

2. The display panel of claim 1, further comprising:
a second switching transistor transmitting a second data signal from the second data line to a second switching node located in a direction further away from the first data line with respect to the second data line in response to the scan signal; and
a second common line located between the second switching node and the second data line in the first direction and extending in the second direction, wherein a second constant voltage is applied to the second common line.

3. The display panel of claim 2, wherein a level of the first constant voltage is different from a level of the second constant voltage.

4. The display panel of claim 2, further comprising:
a third data line located in the direction further away from the first data line with respect to the second data line and extending in the second direction; and
a connection electrode electrically connected to the second common line,
wherein the second switching node is located between the second common line and the third data line in the first direction, and the connection electrode is located between the second switching node and the third data line in the first direction.

5. The display panel of claim 4, wherein the second switching node and the connection electrode extend in the second direction.

6. The display panel of claim 5, wherein a length of the connection electrode in the second direction is greater than a length of the second switching node in the second direction.

7. The display panel of claim 4, wherein the second common line and the connection electrode are integrally formed as a single unitary indivisible body.

8. The display panel of claim 4, wherein the second common line has a potential of a reference voltage to be transmitted to the first switching node and the second switching node.

9. The display panel of claim 1, further comprising:
a third data line located in a direction further away from the first data line with respect to the first switching node and extending in the second direction;
a third switching transistor transmitting a third data signal from the third data line to a third switching node located between the third data line and the first switching node in the first direction, in response to the scan signal; and
a connection electrode located between the third data line and the third switching node in the first direction,
wherein the connection electrode is disposed over the first data line and is electrically connected to a power line transmitting a driving voltage.

10. The display panel of claim 9, wherein the connection electrode and the third switching node extend in the second direction.

11. The display panel of claim 10, wherein a length of the connection electrode in the second direction is greater than a length of the third switching node in the second direction.

12. An electronic apparatus comprising:
a processor; and
a display panel controlled by the processor,
wherein the display panel includes:
a first data line and a second data line arranged along a first direction, each of the first data line and the second data line extending in a second direction crossing the first direction;
a first switching transistor transmitting a first data signal from the first data line to a first switching node located in a direction further away from the second data line with respect to the first data line in response to a scan signal; and
a first common line located between the first switching node and the first data line in the first direction and extending in the second direction, wherein a first constant voltage is applied to the first common line.

13. The electronic apparatus of claim 12, further comprising:
a second switching transistor transmitting a second data signal from the second data line to a second switching node located in a direction further away from the first data line with respect to the second data line in response to the scan signal; and
a second common line located between the second switching node and the second data line in the first direction and extending in the second direction, wherein a second constant voltage is applied to the second common line.

14. The electronic apparatus of claim 13, further comprising:
a third data line located in the direction further away from the first data line with respect to the second data line and extending in the second direction; and
a connection electrode electrically connected to the second common line,
wherein the second switching node is located between the second common line and the third data line in the first direction, and the connection electrode is located between the second switching node and the third data line in the first direction.

15. The electronic apparatus of claim 14, wherein the second switching node and the connection electrode extend in the second direction.

16. The electronic apparatus of claim 15, wherein a length of the connection electrode in the second direction is greater than a length of the second switching node in the second direction.

17. The electronic apparatus of claim 14, wherein the second common line and the connection electrode are integrally formed as a single unitary indivisible body.

18. The electronic apparatus of claim 12, further comprising:
a third data line located in a direction further away from the first data line with respect to the first switching node and extending in the second direction;
a third switching transistor transmitting a third data signal from the third data line to a third switching node located between the third data line and the first switching node in the first direction, in response to the scan signal; and
a connection electrode located between the third data line and the third switching node in the first direction,
wherein the connection electrode is disposed over the first data line and is electrically connected to a power line transmitting a driving voltage.

19. The electronic apparatus of claim 18, wherein the connection electrode and the third switching node extend in the second direction.

20. The electronic apparatus of claim 19, wherein a length of the connection electrode in the second direction is greater than a length of the third switching node in the second direction.
